(19) United States
(12) Patent Application Publication
(10) Pub. No.: US 2026/0101521 A1
(43) Pub. Date: Apr. 9, 2026

(54) SEMICONDUCTOR MODULE

(71) Applicant: RESEARCH ASSOCIATION FOR ADVANCED SYSTEMS, Tokyo (JP)

(72) Inventors: Atsutake KOSUGE, Tokyo (JP); Tadahiro KURODA, Tokyo (JP)

(21) Appl. No.: 19/406,076

(22) Filed: Dec. 2, 2025

Related U.S. Application Data
(63) Continuation of application No. PCT/JP2024/018677, filed on May 21, 2024.

(30) Foreign Application Priority Data
Jun. 20, 2023 (JP) 2023-101093

(51) Int. Cl. H10B 80/00; H10D 80/30; H10W 80/00; H10W 90/00; H10W 90/10; H10W 90/26

(52) U.S. Cl. CPC H10B 80/00; H10D 80/30; H10W 80/314; H10W 90/10; H10W 90/26; H10W 90/724; H10W 90/7295

(57) ABSTRACT

A semiconductor module includes a first semiconductor chip including a first surface and a second surface parallel to a first direction and a second direction, a sub-semiconductor cube including a second semiconductor chip and a logic chip electrically connected to the second semiconductor chip stacked in the first direction, and a semiconductor cube arranged on the second surface, wherein the logic chip includes a plurality of first inductors arranged parallel to a third direction perpendicular to the first direction and the second direction, the first semiconductor chip includes a plurality of routers and a plurality of second inductors arranged parallel to the second surface, a plurality of circuits in the first semiconductor chip are electrically connected using the plurality of routers, and the logic chip and the first semiconductor chip are configured to be able to communicate contactlessly using the plurality of first inductors and the plurality of second inductors.

### CROSS-REFERENCE TO RELATED APPLICATIONS

This application is a Continuation of International Patent Application No. PCT/JP2024/018677, filed on May 21, 2024, which claims the benefit of priority to Japanese Patent Application No. 2023-101093, filed on Jun. 20, 2023, the entire contents of which are incorporated herein by reference.

### FIELD

An embodiment of the present invention relates to a semiconductor module.

### BACKGROUND

In recent years, power consumption of electronic computers such as data centers has rapidly increased. In addition, with an increase in the amount of data communication, the power consumption of an electronic computer is rapidly increasing, the memory capacity of the electronic computer is increased, and the demand for reduction in power consumption and an increase in capacity of the electronic computer is increasing. For example, the electronic computer includes a plurality of logic chips and a plurality of memory chips electrically connected to the plurality of logic chips. The logic chip is, for example, a semiconductor chip on which a logic circuit is mounted, and the memory chip is a semiconductor chip on which a memory circuit is mounted. Data communication in an electronic computer is performed between a logic chip and a memory chip, for example. For example, reducing a distance between the logic chip and the memory chip by stacking and three-dimensionally mounting the logic chip and the memory chip is one effective solution for reducing the power consumption of the electronic computer.

As an example of a three-dimensional mounting method, a semiconductor module in which a structure (vertically stacked memory cube) in which a plurality of memory chips is stacked is arranged on a substrate or a logic chip such that the plurality of memory chips is parallel to the substrate or the logic chip, or a semiconductor module in which a structure (horizontally stacked memory cube) in which a plurality of memory chips are stacked is vertically placed on a substrate or a logic chip such that the plurality of memory chips is perpendicular to the substrate or the logic chip is known. The vertically stacked memory cube and the substrate or the logic chip are electrically connected to each other using, for example, a TSV, a microbump, or the like. Further, a technique of performing contactless communication between a chip and a substrate is known.

### SUMMARY

A semiconductor module includes a first semiconductor chip including a first surface parallel to a first direction and a second direction intersecting the first direction, and a second surface parallel to the first surface, and a semiconductor cube arranged on the second surface, including a sub-semiconductor cube in which a second semiconductor chip and a logic chip electrically connected to the second semiconductor chip are stacked in the first direction. The logic chip includes a plurality of first inductors arranged parallel to a third direction perpendicular to the first and second directions, the first semiconductor chip includes a plurality of routers and a plurality of second inductors arranged parallel to the second surface, a plurality of circuits within the first semiconductor chip is electrically connected using the plurality of routers, and the logic chip and the first semiconductor chip are configured to enable contactless communication using the plurality of first inductors and the plurality of second inductors.

In the semiconductor module, the logic chip may control the plurality of routers via the plurality of first inductors and the plurality of second inductors, and may be configured to connect the plurality of circuits in the first semiconductor chip and the second semiconductor chip.

In the semiconductor module, each of the plurality of routers may include a switch.

In the semiconductor module, the logic chip may include a first electrode, and the second semiconductor chip may include a second electrode configured so as to join with the first electrode by fusion bonding.

In the semiconductor module, the semiconductor cube may include a plurality of the sub-semiconductor cubes stacked in the first direction, and the plurality of sub-semiconductor cubes may be configured to be capable of contactless communication with each other via the plurality of second inductors using the plurality of first inductors included in each of the sub-semiconductor cubes.

In the semiconductor module, the semiconductor cube may include at least one type of memory chip different from the second semiconductor chip and may include a configuration in which the sub-semiconductor cube and the at least one type of memory chip are stacked in the first direction, wherein the at least one type of memory chip may include a plurality of third inductors, and at least one second inductor of the plurality of second inductors may be capable of contactless communication with at least one third inductor of the plurality of third inductors.

In the semiconductor module, the semiconductor module may include a plurality of the semiconductor cubes, and the plurality of the semiconductor cubes may be arranged spaced apart from one another on the second surface.

In the semiconductor module, the plurality of sub-semiconductor cubes may be arranged spaced apart from one another on the second surface.

In the semiconductor module, the semiconductor cube may include at least one type of memory chip different from the second semiconductor chip, and may include a configuration in which the sub-semiconductor cube and the at least one type of memory chip are stacked in the first direction, the second semiconductor chip may be arranged parallel to the third direction and includes a plurality of fourth inductors capable of contactless communication with each of the plurality of second inductors and a plurality of fifth inductors different from the plurality of fourth inductors, and the at least one type of memory chip may include a plurality of sixth inductors capable of contactless communication with each of the plurality of fifth inductors.

### EFFECT OF THE INVENTION

According to an embodiment of the present invention, it is possible to provide a semiconductor module using inductor communication that has good thermal conductivity and excellent heat dissipation characteristics, as well as suppressing signal delays and reducing power consumption.

### BRIEF DESCRIPTION OF DRAWINGS

FIG. 1 is a perspective view showing a configuration of a semiconductor module according to a first embodiment of the present invention.

FIG. 2 is a cross-sectional view showing the configuration of the semiconductor module according to the first embodiment of the present invention.

FIG. 3A is a perspective view showing an inductor group included in a plurality of logic chips and an inductor group included in a magnetic field coupling chip interface router chip (Through Chip Interface Router Chip (TCI router chip)) according to the first embodiment of the present disclosure.

FIG. 3B is a perspective view showing the configuration of an inductor on the logic chip and an inductor on the TCI router chip shown in FIG. 3A.

FIG. 4 is a schematic diagram showing configurations of a semiconductor cube and the TCI router chip according to the first embodiment of the present invention.

FIG. 5 is a schematic diagram showing the configuration of the TCI router chip according to the first embodiment of the present invention.

FIG. 6 is a schematic diagram showing a configuration of a logic chip according to the first embodiment of the present invention.

FIG. 7 is a perspective view showing a configuration of the logic chip according to the first embodiment of the present invention.

FIG. 8 is a cross-sectional view showing a cross-sectional configuration of the logic chip along a line A1-A2 shown in FIG. 6.

FIG. 9 is a schematic diagram showing the configuration of a SRAM (Static Random Access Memory) chip according to the first embodiment of the present invention.

FIG. 10 is a perspective view showing the configuration of a SRAM chip according to the first embodiment of the present invention.

FIG. 11 is a cross-sectional view showing a cross-sectional configuration of a SRAM chip along a line B1-B2 shown in FIG. 9.

FIG. 12 is a schematic diagram showing the configuration of the TCI router chip according to the first embodiment of the present invention.

FIG. 13 is a perspective view showing the configuration of the TCI router chip in accordance with the first embodiment of the present invention.

FIG. 14 is a cross-sectional view showing a cross-sectional configuration of the TCI router chip along a line C1-C2 shown in FIG. 12.

FIG. 15 is a sectional view showing a configuration of a semiconductor module according to a second embodiment of the present invention.

FIG. 16 is a schematic diagram showing a configuration of a semiconductor cube and a TCI router chip according to the second embodiment of the present invention.

FIG. 17 is a cross-sectional view showing a cross-sectional configuration of a DRAM (Dynamic Random Access Memory) chip according to the second embodiment.

FIG. 18 is a cross-sectional view showing a cross-sectional structure of an NVM (Non Volatile Memory) chip according to the second embodiment.

FIG. 19 is a sectional view showing a configuration of a semiconductor module according to a third embodiment of the present invention.

FIG. 20 is a schematic diagram showing configurations of a plurality of semiconductor cubes and a TCI router chip according to the third embodiment of the present invention.

FIG. 21 is a sectional view showing a configuration of a semiconductor module according to a fourth embodiment of the present invention.

FIG. 22 is a schematic diagram showing configurations of a plurality of sub-semiconductor cubes and a TCI router chip according to the fourth embodiment of the present invention.

FIG. 23 is a sectional view showing a configuration of a semiconductor module according to a fifth embodiment of the present invention.

FIG. 24 is a schematic diagram showing configurations of a semiconductor cube and a TCI router chip according to the fifth embodiment of the present invention.

FIG. 25 is a cross-sectional view showing a cross-sectional view of a SRAM chip according to the fifth embodiment of the present invention.

FIG. 26 is a cross-sectional view showing a cross-sectional view of a DRAM chip according to the fifth embodiment of the present invention.

### DESCRIPTION OF EMBODIMENTS

For example, since a memory chip, a substrate, and a logic chip of a well-known semiconductor module are stacked in parallel in a stacking direction, thermal resistance of the semiconductor module associated with an oxide film included in a plurality of stacked memory chips increases. When the thermal resistance of the semiconductor module increases, thermal conductivity of the semiconductor module decreases, and for example, it becomes difficult to heat the logic chip. When it becomes difficult to heat the logic chip, the temperature of the semiconductor module rises, which may cause malfunction of the semiconductor module due to the temperature rise. Further, in order to suppress the malfunction of the semiconductor module, it is necessary to suppress the temperature rise of the semiconductor module to a temperature range in which the semiconductor module operates normally. Therefore, the number of stacked chips in the semiconductor module is limited.

Further, a logic chip of a well-known semiconductor module is connected to an external circuit by using a redistribution layer. As a result, a length of a wiring and a wiring load (capacitance) increase, and a signal transmission delay occurs, calculation performance deteriorates, and power consumption of the chip increases.

In view of such problems, an object of an embodiment of the present invention is to provide a semiconductor module using inductor communication capable of suppressing signal delay and reducing power consumption while having excellent heat conduction and heat removal characteristics and suppressing malfunctions caused by electromagnetic noise and heat.

Hereinafter, embodiments of the present invention will be described with reference to the drawings and the like. However, the present invention can be implemented in many different aspects, and should not be construed as being limited to the description of the embodiments exemplified below. In order to make the description clearer, the drawings may be schematically represented with respect to the width, thickness, shape, and the like of each part as compared with the actual embodiment, but the drawings are merely examples, and do not limit the interpretation of the present invention. In addition, in the present specification and the drawings, the same reference signs (or reference signs with a, b, and the like added after a number) are given to the same elements as those described above with respect to the previous drawings, and detailed description thereof may be omitted as appropriate. Furthermore, the terms “first” and “second” with respect to the respective elements are convenient signs used to distinguish the respective elements, and do not have any further meaning unless otherwise specified.

In one embodiment of the invention, in the case where a member or region is “above (or below)” another member or region, this includes not only a case where it is directly above (or directly below) the other member or region, unless otherwise limited, but also a case where it is above (or below) the other member or region, that is, a case where another component is included between above (or below) the other member or region.

In an embodiment of the present disclosure, a direction D1 intersects a direction D2, and a direction D3 intersects the direction D1 and the direction D2 (a plane D1D2). The direction D1 is referred to as a first direction, the direction D2 is referred to as a second direction, and the direction D3 is referred to as a third direction.

In one embodiment of the present invention, in the case where the terms “identical” and “matching” are used, the terms “identical” and “matching” may include a margin of error within the design range. In addition, in an embodiment of the present invention, in the case where an error in the range of design is included, the expressions “substantially identical” and “substantially matching” may be used in some cases.

### First Embodiment

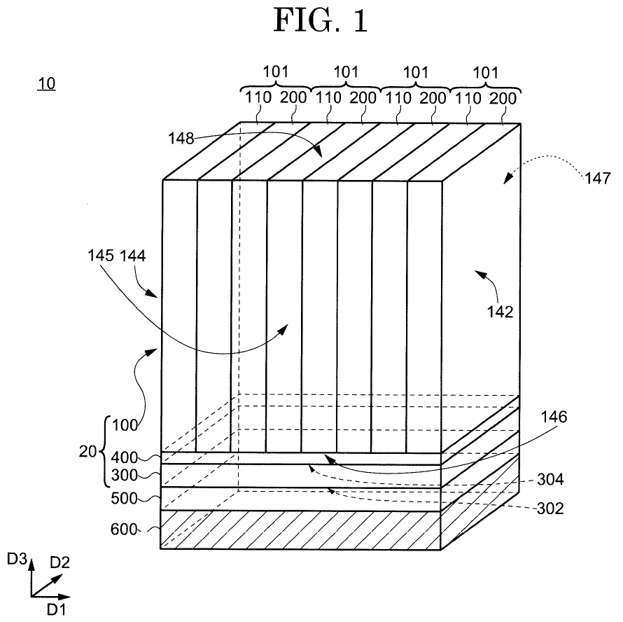

A semiconductor module 10 according to the first embodiment will be described with reference to FIG. 1 to FIG. 14.

### 1-1. Overview of Semiconductor Module 10

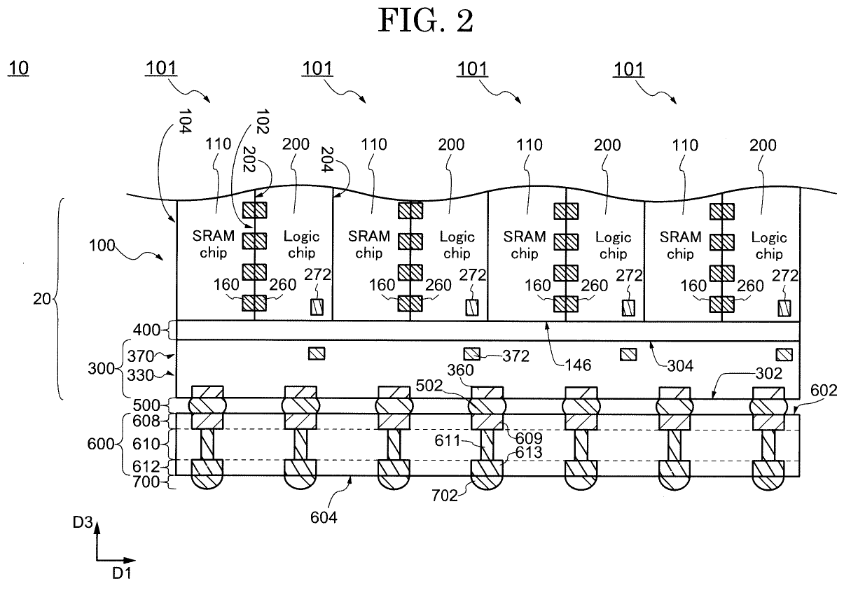

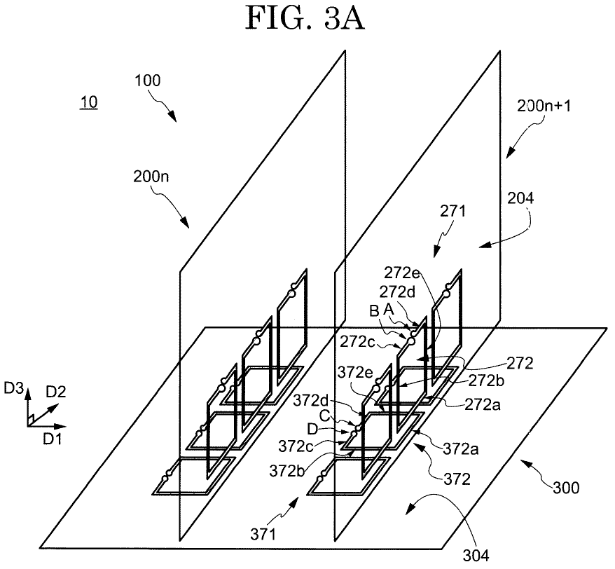

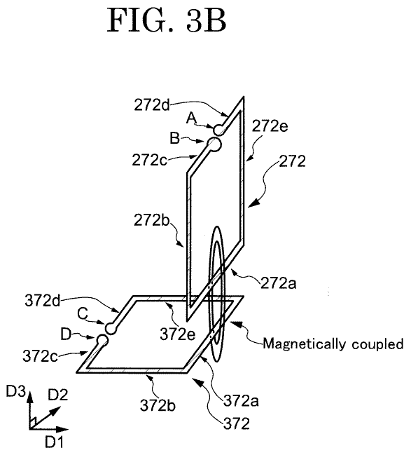

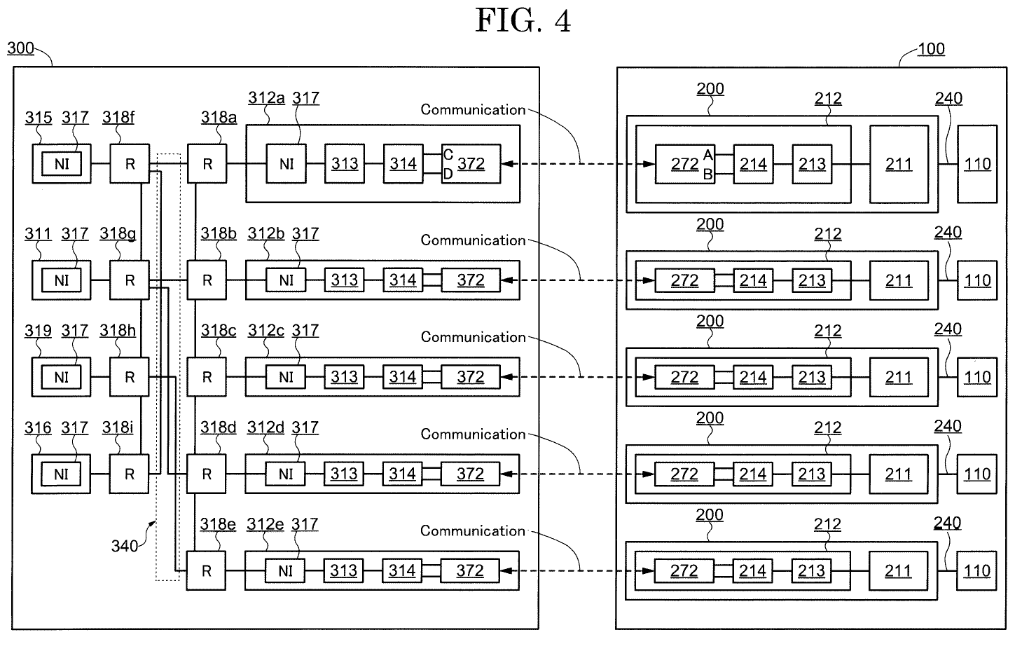

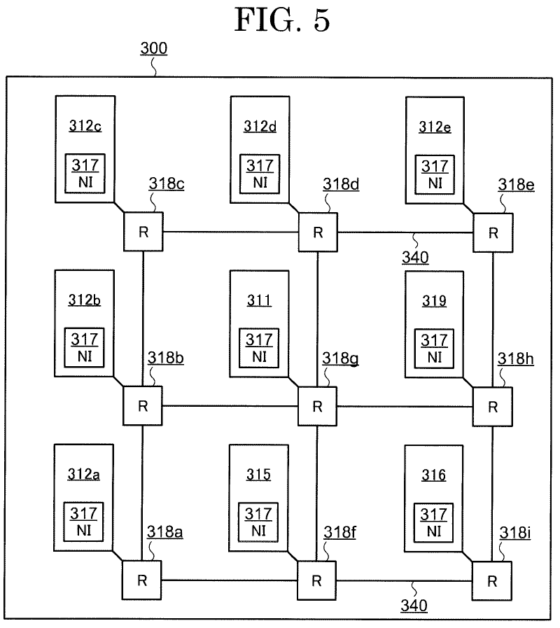

An overview of the semiconductor module 10 will be described with reference to FIG. 1 to FIG. 5. FIG. 1 is a perspective view showing a configuration of the semiconductor module 10. FIG. 2 is a cross-sectional view showing the configuration of the semiconductor module 10. FIG. 3A is a perspective view showing an inductor group 271 included in a plurality of logic chips 200 included in the semiconductor module 10, and an inductor group 371 included in a magnetic field coupling chip interface router chip (Through Chip Interface Router Chip (TCI router chip)) 300, FIG. 3B is a perspective view showing a configuration of an inductor 272 on the logic chip 200 and an inductor 372 on the TCI router chip 300 shown in FIG. 3A. FIG. 4 is a schematic diagram showing a configuration of a semiconductor cube 100 and the TCI router chip 300 included in the semiconductor module 10. FIG. 5 is a schematic diagram showing the configuration of the TCI router chip 300 in the semiconductor module 10.

### 1-1-1. Overall Configuration of Semiconductor Module 10

An overall configuration of the semiconductor module 10 will be described with reference to FIG. 1 and FIG. 2.

As shown in FIG. 1 or FIG. 2, the semiconductor module 10 includes the semiconductor cube 100, the TCI router chip 300, the logic chip 200, and an adhesive layer 400. For example, a stacked body 20 includes the semiconductor cube 100, the TCI router chip 300, the logic chip 200, and the adhesive layer 400. The semiconductor module 10 may include a bump layer 500, a package substrate 600, and a bump layer 700. The TCI router chip 300 may be referred to as a first semiconductor chip.

The semiconductor cube 100 includes a sub-semiconductor cube 101 in which the logic chip 200 and a SRAM chip 110 electrically connected to the logic chip 200 are stacked in the direction D1. The semiconductor cube 100 includes a configuration in which a plurality of sub-semiconductor cubes 101 is stacked in the direction D1. Each of the plurality of logic chips 200 has a similar configuration including a plurality of through electrodes 260, and a plurality of inductor groups 272 (first inductor). Each of a plurality of SRAM chips 110 has a similar configuration including a plurality of through electrodes 160. The semiconductor cube 100 includes a first surface 142 parallel to the directions D2 and D3 and a second surface 144 opposite the first surface 142 and parallel to the first surface 142 with respect to the direction D1. The semiconductor cube 100 also includes a first side surface 145 perpendicular to the first surface 142 and second surface 144, a second side surface 146 adjacent to the first side surface 145, a third side surface 147 adjacent to the second side surface 146, and a fourth side surface 148 adjacent to the third side surface 147 and first side surface 145. The second side surface 146 abuts against the adhesive layers 400 and is positioned to face a second surface 304 of the TCI router chip 300, with the semiconductor cube 100 arranged on the second surface 304 of the TCI router chip 300. The SRAM chip 110 may be referred to as a second semiconductor chip.

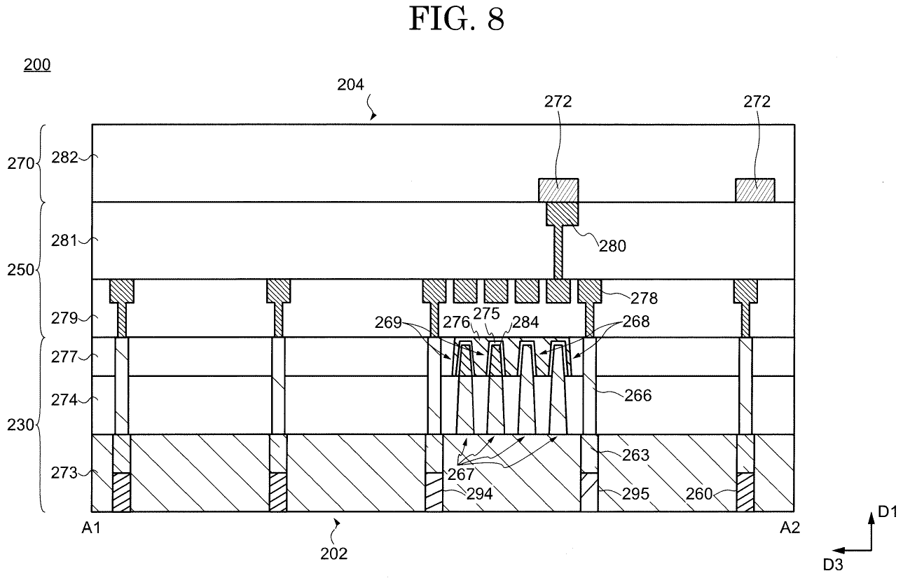

The logic chip 200 includes a first surface 202, which is an exposed surface of the logic chip 200, and a second surface 204, which is an exposed surface of the logic chip 200 opposite the first surface 202. The plurality of through electrodes 260 is exposed to the first surface 202. A plurality of inductors 272 is arranged proximate to the second surface 204. The plurality of inductors 272 is arranged side by side in parallel and spaced apart from the second side surface 146 D2. Although details will be described later, a substrate 273 included in the logic chip 200 (for example, see FIG. 8) is located below the (first surface 202 side) with respect to the direction D1, and an N-type transistor 268 and a P-type transistor 269 (for example, see FIG. 8) are stacked above the substrate 273 with respect to the direction D1. The first surface 202 of the logic chip 200 is arranged to face the first surface 102 of the SRAM chip 110, in the sub-semiconductor cube 101.

If each of the plurality of logic chips 200 is not distinguished, the logic chip is represented as the logic chip 200. If each of the plurality of logic chips 200 is distinguished, the logic chip is represented as a logic chip 200n, logic chip 200n+1, and the like. The plurality of logic chips 200 included in the semiconductor cube 100 includes, for example, the logic chip 200n (see FIG. 3A or FIG. 3B) and the logic chip 200n+1 (see FIG. 3A or FIG. 3B) arranged adjacent to the logic chip 200n. In addition, the semiconductor cube 100 includes a configuration in which the four sub-semiconductor cubes 101 are stacked in the direction D1. The number of stacked sub-semiconductor cubes 101 shown in FIG. 1 is an example, and the number of stacked sub-semiconductor cubes 101 is not limited to four (four layers) shown in FIG. 1. The number of stacked sub-semiconductor cubes 101 may be appropriately selected based on the application, specifications, and the like of the semiconductor module 10.

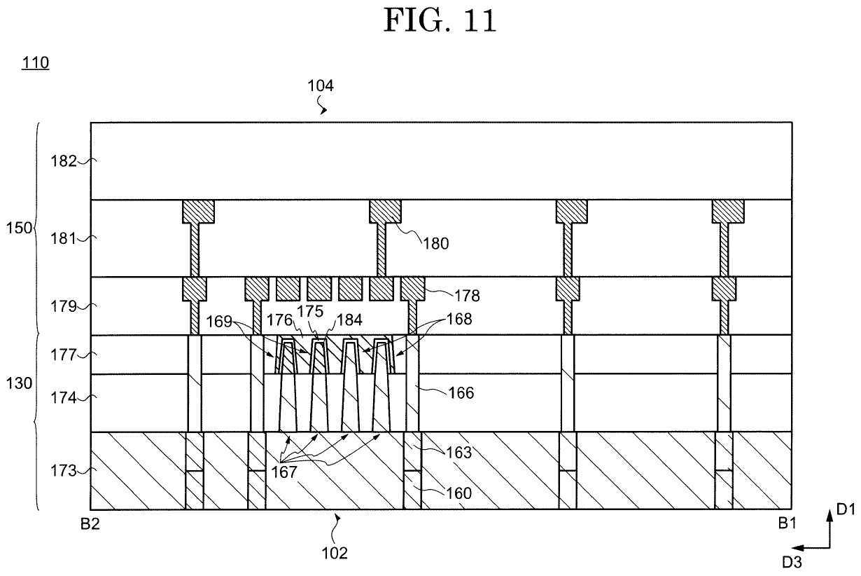

The SRAM chip 110 includes a first surface 102, which is an exposed surface of the SRAM chip 110, and a second surface 104, which is an exposed surface of the SRAM chip 110 opposite to the first surface 102. The first surface 102 is a surface that faces and contacts the first surface 202 of the logic chip 200. The plurality of through electrodes 160 is exposed to the first surface 102. Although details will be described later, a substrate 173 included in the SRAM chip 110 (for example, see FIG. 11) is located below with respect to the direction D1 (first surface 102 side), and an N-type transistor 168 and a P-type transistor 169 (for example, see FIG. 11) are stacked above the substrate 173 with respect to the direction D1.

Further, the SRAM chip 110 is stacked (bonded) with the logic chip 200. In this case, each of the plurality of through electrodes 160 is bonded to a corresponding plurality of through electrodes 260, and the SRAM chip 110 is electrically connected to the logic chip 200. The chips can be stacked (bonded) together using techniques such as fusion bonding and silicon direct bonding (Silicon Direct Bonding (SDB)). Since welding and silicon direct bonding are well-known techniques in the art, a detailed description will be omitted here. Incidentally, the plurality of through electrodes 160 and the plurality of through electrodes 260 are formed, for example, using a conductor made of metal. Conductors made of metal as a material are, for example, a conductor containing copper or the like. Each of the through electrode 160 and the through electrode 260 may be referred to as, for example, the second electrode and the first electrode.

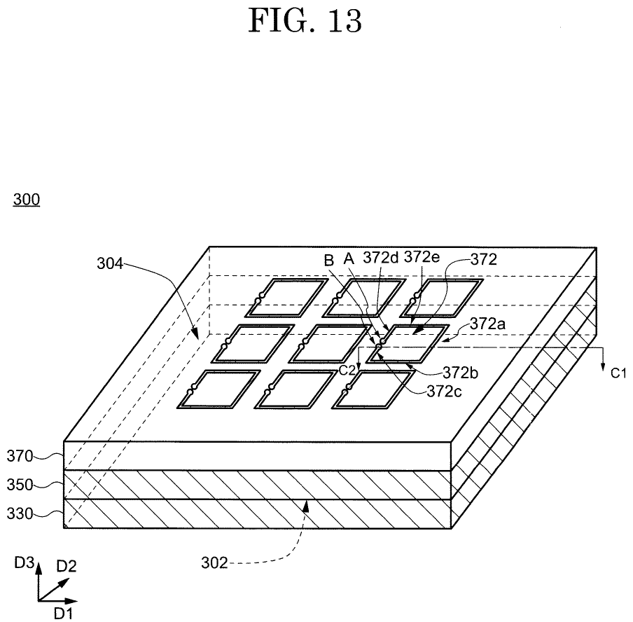

The TCI router chip 300 includes, for example, a transistor layer 330 and an inductor layer 370 stacked on the transistor layer 330. The transistor layers 330 include a first surface 302, which is an exposed surface of the TCI router chip 300, and a plurality of through electrodes 360. The plurality of through electrodes 360 is exposed to the first surface 302. The inductor layers 370 include the second surface 304, which is an exposed surface of the TCI router chip 300 opposing the first surface 302, and a plurality of inductors 372. The first surface 302 and the second surface 304 are surfaces parallel to the direction D1 and the direction D2. The first surface 302 is positioned to face a first surface 602 of the package substrate 600 and is connected to the first surface 602 of the package substrate 600 using the bump layer 500. Further, the second surface 304 is positioned so as to be in contact with the adhesive layer 400 and face the second side surface 146 of the semiconductor cube 100. In addition, although the details will be explained later, the TCI router chip 300 includes a wiring layer 350 (for example, see FIG. 13) between the transistor layer 330 and the inductor layer 370. The transistor layer 330, the wiring layer 350, and the inductor layer 370 are stacked in this order in the direction D3.

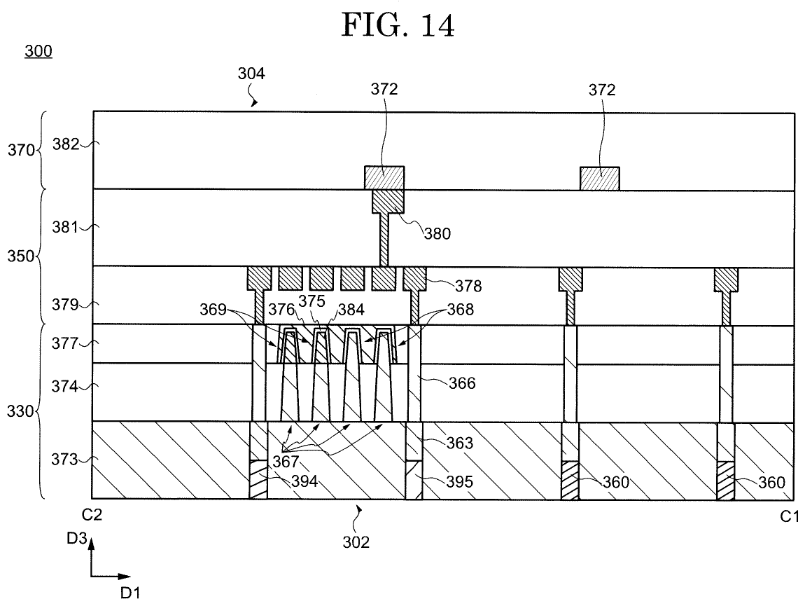

Further, although the details will be explained later, a substrate 373 (for example, see FIG. 14) included in the TCI router chip 300 is positioned below the direction D3 (toward the first surface 302), and an N-type transistor 368 and a P-type transistor 369 (see, for example, FIG. 14) are stacked above the substrate 373 with respect to the direction D3. That is, the stacking direction of the layers constituting the TCI router chip 300 is upward in the direction D3. For example, a mounting structure in which a stacking direction is upward in the direction D3 is called face-up mounting, and a mounting structure in which a stacking direction is downward in the direction D3 is called face-down mounting. The first surface 302 of the TCI router chip 300 is arranged on the package substrate 600, and the TCI router chip 300 is face-up mounted on the package substrate 600, in the semiconductor module 10.

The adhesive layer 400 is arranged between the semiconductor cube 100 and the TCI router chip 300 to adhere the semiconductor cube 100 and the TCI router chip 300. The adhesive layer 400 may be, for example, an adhesive containing an epoxy resin, an acrylic polymer, or the like, and may be a die bonding film (Die Bonding Film (DBF)) containing an epoxy resin or an acrylic polymer, or an adhesive film such as a die attached film (Die Attached Film (DAF)), or the like.

The package substrate 600 includes a multilayer wiring structure in which wirings and insulating layers are alternately stacked, and the package substrate 600 includes, for example, a second surface 604 and the first surface 602, which are exposed surfaces of the package substrate 600, and a plurality of wiring layers 608, 610, and 612. The wiring layers 608, 610, and 612 are arranged in the direction D1 and the direction D2, and are stacked in this order from top to bottom in the direction D3. The pluralities of wiring layers 608, 610, and 612 include a plurality of wirings 609, a plurality of wirings 611, and a plurality of wirings 613. The plurality of wirings 609 is exposed to the first surface 602, and the plurality of wirings 613 is exposed to the second surface 604. For example, the wiring 609 is electrically connected to the wiring 611, and the wiring 611 is electrically connected to the wiring 613. In FIG. 2, insulating layers alternately stacked with the wiring are not shown. The number of stacked layers of the multilayer wiring structure of the package substrate 600 is not limited to the number of stacked layers (three layers) shown in FIG. 2. The number of layers of the multilayer wiring structure of the package substrate 600 can be appropriately changed based on the application or specification of the semiconductor module 10.

Further, the package substrate 600 is electrically connected to the stacked body 20 via a plurality of bumps 502 included in the bump layer 500 arranged between the stacked body 20 and the package substrate 600. Further, the package substrate 600 is connected to an external substrate, an external circuit, and the like via a plurality of bumps 702 included in the bump layer 700. Specifically, each of the plurality of wirings 609 exposed on the first surface 602 is electrically connected to each of the plurality of through electrodes 360 by using the bump 502, and each of the plurality of through electrodes 613 exposed on the second surface 604 is connected to an external substrate, an external circuit, or the like by using the bump 702.

The semiconductor module 10 includes the semiconductor cube 100 vertically placed on the TCI router chip 300 in the direction D3, and has a lower thermal resistivity than a configuration including a memory chip and a logic chip stacked in parallel in the direction D1 and the direction D2. Therefore, since the semiconductor module 10 has high thermal conductivity and excellent heat dissipation characteristics, it is possible to suppress malfunctions caused by a temperature rise of the semiconductor module. Therefore, limitation of the number of stacked chips in the semiconductor module 10 is relaxed compared to the configuration including a memory chip and a logic chip stacked in parallel in the direction D1 and the direction D2. Further, since the semiconductor module 10 has a high thermal conductivity, and has excellent heat removal characteristics, the semiconductor module 10 may include a configuration in which logic chips with large power consumption are stacked.

Further, the semiconductor module 10 also includes the logic chips 200 and the SRAM chips 110 that are bonded using fusion bonding. Therefore, the logic chip 200 is tightly coupled to the SRAM chip 110, and a length of the wiring connecting the logic chip 200 and the SRAM chip 110 and the wiring load (capacitance) is suppressed. Consequently, the semiconductor module 10 is able to suppress the delay of signal transmission that occurs between the logic chip 200 and the SRAM chip 110.

### 1-1-2. Overview of Inductor 272 and Inductor 372

Overviews of the inductor 272 and the inductor 372 will be described referring to FIG. 3A and FIG. 3B. Configurations that are the same as or similar to those in FIG. 1 and FIG. 2 will be described as necessary.

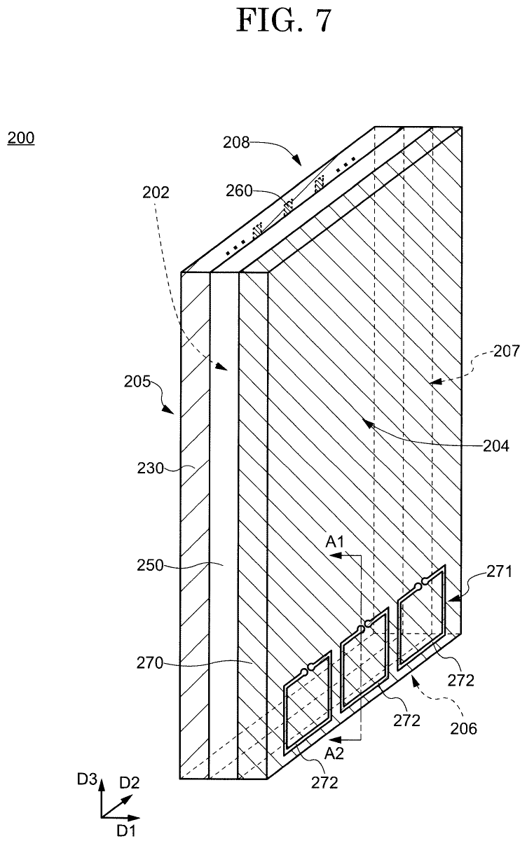

As described above, since the plurality of logic chips 200 has the same configuration, the configuration of the logic chip 200n+1 will be described here, and the configuration of the logic chip 200n will be described as needed. The logic chip 200n+1 includes an inductor layer 270 (for example, see FIG. 7 and FIG. 8). The inductor layer 270 includes a plurality of inductor groups 271, and each of the plurality of inductor groups 271 includes the plurality of inductors 272.

As shown in FIG. 3A or FIG. 3B, each of the plurality of inductors 272 is arranged in the direction D3 perpendicular to the direction D1 and the direction D2 (that is, the second surface 304).

As described above, the plurality of inductors 272 is arranged parallel to and spaced apart from the second side surface 146 and aligned in the direction D2. Each of the plurality of inductors 272 includes a terminal A, a terminal B, a first part 272a, a second part 272b, a third part 272c, a fourth part 272d, and a fifth part 272e. Although details will be described later, the inductor 272 is electrically connected to a transmission/reception circuit 214 (see FIG. 4) using the terminal A and the terminal B.

The fourth part 272d extends in the direction D2, one end of the fourth part 272d is electrically connected to the terminal A, and the other end of the fourth part 272d is electrically connected to one end of the fifth part 272e. The fifth part 272e extends in the direction D3 and the other end of the fifth part 272e is electrically connected to one end of the first part 272a. The first part 272a extends in the direction D2 and the other end of the first part 272a is electrically connected to one end of the second part 272b. The second part 272b extends in the direction D3 and the other end of the second part 272b is electrically connected to one end of the third part 272c. The third part 272c extends in the direction D2 and the other end of the third part 272c is electrically connected to the terminal B.

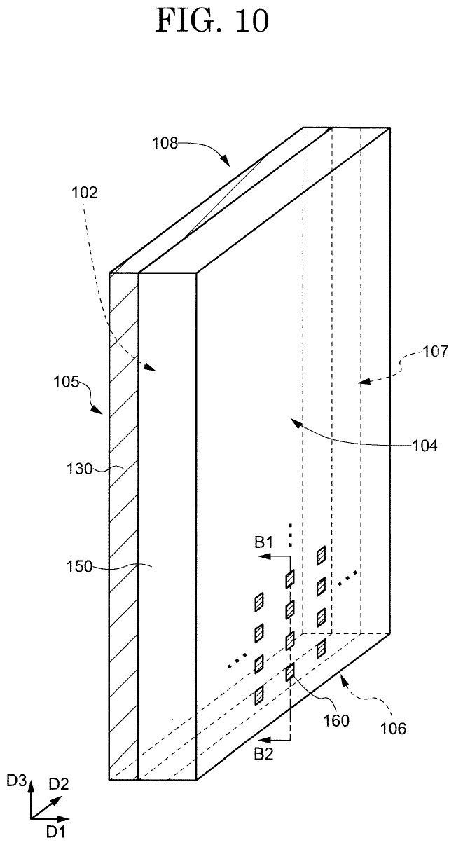

The TCI router chip 300 includes the inductor group 371 that includes the plurality of inductors 372 that are parallel to a position where the plurality of inductors 272 is arranged and that are arranged parallel to and proximate to the second surface 304. In addition, the TCI router chip 300 includes the inductor layer 370 (see, for example, FIG. 10 and FIG. 11), and the inductor layer 370 includes the plurality of inductors 372. The plurality of inductors 372 is arranged in a matrix along the direction D1 and the direction D2. Each of the plurality of inductors 372 includes a terminal C, a terminal D, a first part 372a, a second part 372b, a third part 372c, a fourth part 372d, and a fifth part 372e. Although details will be described later, the inductor 372 is electrically connected to a transmission/reception circuit 314 using the terminal C and the terminal D.

The fourth part 372d extends in the direction D2, one end of the fourth part 372d is electrically connected to the terminal C, and the other end of the fourth part 372d is electrically connected to one end of the fifth part 372e. The fifth part 372e extends in the direction D1 and the other end of the fifth part 372e is electrically connected to one end of the first part 372a. The first part 372a extends in the direction D2 and the other end of the first part 372a is electrically connected to one end of the second part 372b. The second part 372b extends in the direction D1 and the other end of the second part 372b is electrically connected to one end of the third part 372c. The third part 372c extends in the direction D2 and the other end of the third part 372c is electrically connected to the terminal D.

As shown in FIG. 3A and FIG. 3B, in the semiconductor module 10, the shape of the inductor 272 when a plane parallel to the direction D2 and the direction D3 is viewed from the direction D1, and the shape of the inductor 372 when a plane parallel to the direction D1 and the direction D2 is viewed from the direction D3 are, for example, quadrangular shapes. Since the logic chip 200 is standing perpendicular to the TCI router chip 300, the inductor 272 is arranged opposite to the inductor 372 by 90 degrees. Further, when a plane parallel to the direction D1 and the direction D2 is viewed from the direction D3, the first part 272a of the inductor 272 overlaps the first part 372a of the inductor 372. Among the plurality of inductors 272 and the plurality of inductors 372, one inductor 272 and one inductor 372 opposed to each other are magnetically coupled to each other, so that the inductors can communicate with each other in a one-to-one manner in a contactless manner. The communication between the inductors associated with the magnetic field coupling is called, for example, inductor communication, signal communication, data communication, or the like. In addition, the shape of the inductor 272 and the shape of the inductor 372 are not limited to a quadrangular shape. For example, the shape of the inductor 272 and the shape of the inductor 372 may be trapezoidal or pentagonal. The shape of the inductor 272 and the shape of the inductor 372 may be any shape capable of inductor communication.

As shown in FIG. 3B, for example, the inductor 272 and the inductor 372 are opposed to each other at 90 degrees, and can communicate one-to-one by magnetic field coupling. More specifically, effective inductor communication is performed by the first part 272a of the inductor 272 and the first part 372a of the inductor 372. The first part 272a mainly has a function of performing inductor communication with the first part 372a. The second part 272b, the third part 272c, the fourth part 272d, and the fifth part 272e excluding the first part 272a mainly have a function of supplying current to the first part 272a, in the inductor 272. Similar to the inductor 272, in the inductor 372, the second part 372b, the third part 372c, the fourth part 372d, and the fifth part 372e except for the first part 372a mainly have a function of supplying current to the first part 372a.

The inductor 372 has the same configuration and function as the inductor 272. In addition, in the semiconductor module 10, viewing a plane parallel to the direction D2 and the direction D3 from the direction D1 is referred to as a front view, and viewing a plane parallel to the direction D1 and the direction D2 from the direction D3 may be referred to as a plan view.

### 1-1-3. Circuit Configuration of Semiconductor Module 10

A schematic circuit configuration of the semiconductor module 10 will be described with reference to FIG. 4 and FIG. 5. As shown in FIG. 4, the semiconductor cube 100 and the TCI router chip 300 are connected based on inductor communication, and the logic chip 200 and the SRAM chip 110 are electrically connected by using a signal bus 240. As shown in FIG. 5, the circuits in the TCI router chip 300 are electrically connected via a plurality of network routers (Router(R)) 318 (318a to 318i) using signal buses 340.

As described in the section “1-1-1. Overall Configuration of Semiconductor Module 10”, the semiconductor cube 100 includes, as an example, the plurality of sub-semiconductor cubes 101. Each of the plurality of sub-semiconductor cubes 101 includes the logic chip 200 and the SRAM chip 110. The logic chip 200 is electrically connected to the SRAM chip 110 using the signal bus 240. In FIG. 4, reference sign “101” of the sub-semiconductor cube 101 is omitted for clarity of the drawings.

As shown in FIG. 4, the semiconductor cube 100 includes a plurality of magnetic field coupled chip-to-chip interfaces (Through Chip Interface-IO (TCI-IO)) 212 and a plurality of logic modules 211. The plurality of TCI-IOs 212 is electrically connected to the logic module 211. Although the logic chip 200 includes the plurality of TCI-IOs 212, in FIG. 4, the number of the TCI-IO 212 is reduced to one for clarity of the drawings.

The TCI-IO 212 includes the inductor 272, the transmission/reception circuit 214, and a parallel-serial conversion circuit 213. The inductor 272 is electrically connected to the transmission/reception circuit 214 using the terminal A and the terminal B. The transmission/reception circuit 214 is electrically connected to the parallel-serial conversion circuit 213. The parallel-serial conversion circuit 213 is electrically connected to the logic module 211.

As described above, the inductor 272 has the function of performing inductor communication with the inductor 372 of the TCI router chip 300 in a contactless manner.

The transmission/reception circuit 214 has, for example, a function of amplifying a signal (data) received by the inductor 272 and a function of removing noise from the received signal (data). Further, the transmission/reception circuit 214 has a function of transmitting a desired signal (data) converted by using the parallel-serial conversion circuit 213 onto a radio wave, for example. The signal received by the inductor 272 includes a number of parallel signals from the TCI router chip 300. The desired signal includes a number of parallel signals from the logic module 211.

The parallel-serial conversion circuit 213 converts a large number of parallel signals from the TCI router chip 300 into serial signals (serial signal) by parallel-serial conversion in step 1, for example. The serial signal is transferred at high speed using one signal path (wiring). In step 2, the parallel-serial conversion circuit 213 performs serial-parallel conversion on the serial signal immediately before the logic module 211, returns the serial signal to a plurality of parallel signals, and then transmits the plurality of parallel signals to the logic module 211. In the case where the logic module 211 transmits a signal (data) to the TCI router chip 300, the parallel-serial conversion circuit 213 performs step 1 following step 2, for example. The parallel-serial conversion circuit 213 is called, for example, a SerDes circuit (Serialize and Deserialize Circuit).

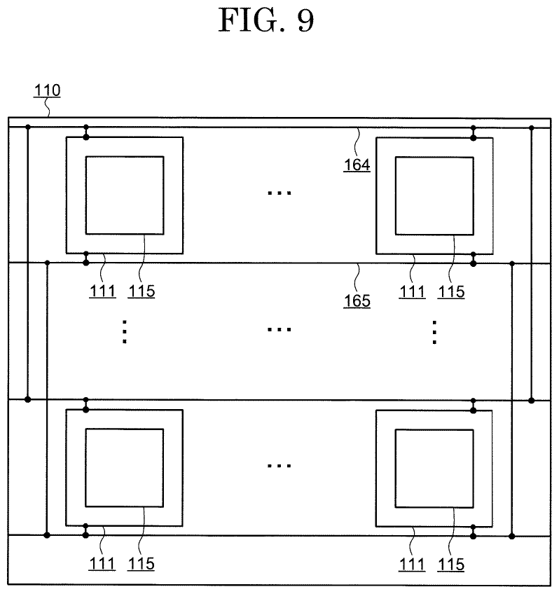

The logic module 211 has functions for controlling transmission of signals (data) to the TCI-IO 212 or reception of signals (data) from the TCI-IO 212. Further, the logic module 211 also has ability to drive a memory module 111 (see FIG. 9) within the SRAM chip 110. For example, the logic module 211 transmits a signal for driving the memory module 111 via the TCI-IO 212. The logic module 211 may include arithmetic circuit such as, for example, a CPU (Central Processing Unit).

As shown in FIG. 4 or FIG. 5, the TCI router chip 300 includes, for example, the plurality of TCI-IOs 312, a plurality of Rs 318, a DRAM interface (DRAMIO) 311, a PCIe interface (PCI Express Interface (PCIeIF)) 315, an Ethernet interface (Ethernet Interface (EIF)) 316, and a memory controller 319.

The TCI-IO 312, the DRAMIO 311, the PCIeIF 315, the EIF 316, and the memory controller 319 are functional blocks that constitute an LSI (Large Scale Integration (large scale integrated circuit)). The functional blocks constituting the LSI are called, for example, IP (Intellectual Property) cores, IP, macros, or the like. The IP cores include a CPU (Central Processing Unit), a GPU (Graphics Processing Unit), memories, or the like.

The configuration and function of the TCI router chip 300 is not limited to the TCI router chip 300 shown in FIG. 4 or FIG. 5. That is, the number and type of the TCI-IO 312 included in the TCI router chip 300 and the number and type of IP cores are not limited to the plurality of TCI-IOs 312, the DRAMIO 311, the PCIeIF 315, the EIF 316 and memory controllers 319. The configuration and function of the TCI router chip 300 is appropriately selected depending on the specifications and applications of the semiconductor module 10, and the number of IP cores included in the semiconductor module 10. For example, the TCI router chip 300 may include a plurality of DRAMIOs 311, may include a plurality of memory controllers 319, and may include an external IO (not shown).

The IP cores, such as the plurality of TCI-IOs 312, the DRAMIO 311, the PCIeIF 315, the EIF 316, and the memory controllers 319 include a network interface (Network Interface (NI)) 317.

In addition, the IP cores, such as the plurality of TCI-IOs 312, the DRAMIO 311, the PCIeIF 315, the EIF 316, and the memory controller 319, may not include the NI 317, the NI 317 may be located outside the plurality of TCI-IOs 312, the DRAMIO 311, the PCIeIF 315, the EIF 316, and the memory controller 319, and each of the plurality of TCI-IOs 312, the DRAMIO 311, the PCIeIF 315, the EIF 316, and the memory controller 319 may be electrically connected to the R 318 corresponding to each circuit via the NI 317.

The IP cores, such as the plurality of TCI-IOs 312, the DRAMIO 311, the PCIeIF 315, EIF 316, and the memory controller 319, are electrically connect to the R 318 corresponding to the NI 317 of the respective IP cores. Thus, the IP cores, such as the plurality of TCI-IOs 312, the DRAMIO 311, the PCIeIF 315, the EIF 316, and the memory controller 319, are connected together in a network form using the plurality of Rs 318. The plurality of Rs 318, for example, are electrically connected using the plurality of signal buses 340.

A network configuration of the IP core using the plurality of Rs 318 may be mesh-like as shown in FIG. 5. The network configuration of the IP core shown in FIG. 5 is an example, and the network configuration of the IP core is not limited to the configuration shown in FIG. 5. The network configuration of the IP core is appropriately selected depending on the specifications and applications of the semiconductor module 10, the number of the IP cores included in the semiconductor module 10, and the like.

The plurality of TCI-IOs 312 includes, for example, TCI-IOs 312a, 312b, . . . , and 312e. If each of the plurality of TCI-IOs 312 is indistinguishable, the TCI-IO is expressed as the TCI-IO 312. If each of the plurality of TCI-IOs 312 is distinguished, the plurality of TCI-IOs is expressed as the TCI-IO 312a, 312b. . . . , 312e and the like. In addition, the number of the plurality of TCI-IOs 312 included in the semiconductor module 10 is not limited, and is appropriately selected depending on the specifications and applications of the semiconductor module 10, the number of the IP cores included in the semiconductor module 10, and the like.

The TCI-IO 312 includes the inductor 372, the transmission/reception circuit 314, a parallel-serial conversion circuit 313, and the NI 317. The inductor 372 is electrically connected to the transmission/reception circuit 314 using the terminal C and the terminal D. The transmission/reception circuit 314 is electrically connected to the parallel-serial conversion circuit 313. The parallel-serial conversion circuit 313 is electrically connected to the NI 317. The TCI-IO 312 (NI 317) is electrically connected to the R 318.

The configurations and functions of the inductor 372, the transmission/reception circuit 314, the parallel-serial conversion circuit 313, and the memory controller 319 are the same as those of the inductor 272, the transmission/reception circuit 214, the parallel-serial conversion circuit 213, and the logic module 211. Therefore, the configurations and functions of the inductor 372, the transmission/reception circuit 314, the parallel-serial conversion circuit 313, and the memory controller 319 will not be described here.

For example, the NI 317 can convert data transmitted and received using the signal bus 340 into a data format corresponding to the IP core electrically connected to the NI 317, and can convert a data format corresponding to the IP core into a data format corresponding to the signal bus 340. As a result, since the semiconductor module 10 can transmit and receive both an address and the data using the signal bus 340, a bus width can be made smaller than that of the module including the signal bus arranged in a concentrated manner. In addition, since the semiconductor module 10 can transmit and receive data without depending on the data format corresponding to the respective IP cores, the number of the signal buses 340 can be suppressed from increasing.

Here, the data transmitted and received using the signal bus 340 includes, for example, addresses that can identify IP cores electrically connected to the NI 317.

The plurality of Rs 318 includes, for example, Rs 318a, 318b, . . . , and 318i. As in the TCI-IO, in the case where each of the plurality of Rs 318 is not distinguished, the plurality of Rs is expressed as R 318. In the case where each of the plurality of Rs 318 is distinguished, the plurality of Rs is expressed as the Rs 318a, 318b, . . . , and 318i, and the like. The number of the plurality of Rs 318 included in the semiconductor module 10 is not limited, and is appropriately selected depending on the specifications and applications of the semiconductor module 10, the number of the IP cores included in the semiconductor module 10, and the like.

Each of the plurality of Rs 318 is electrically connected to the IP core and signal bus 340. Each of the plurality of Rs 318 includes a plurality of switches, and can control a transmission/reception path of the data to/from the respective IP cores connected in a network form based on the addresses. As a result, the semiconductor module 10 can transmit and receive data to and from the desired IP cores among the IP cores connected in the network form by controlling the plurality of switches of the plurality of Rs 318. Further, the semiconductor module 10 can change the arrangement and address of the R 318 without depending on the arrangement of the IP core in accordance with the control of the transmission and reception path of the data to and from the IP core using the R 318, so that the transmission and reception path of the data can be flexibly set.

Further, the R 318 can also function as a repeater (also referred to as a bus buffer) that aggregates a plurality of signal buses 340 and divides the routed signal buses 340 appropriately. Therefore, the semiconductor module 10 can suppress concentration of the plurality of signal buses 340. As a consequence, for example, flexibility of the position of the R 318 can be improved, and constraint of the arrangement of the IP cores connected to the R 318 can be relaxed.

The DRAMIO 311, for example, has a function of transmitting and receiving signals between the DRAM chip and the logic chip 200.

The PCIeIF 315 is, for example, an interface corresponding to a serial bus standard used to connect an expansion card or the like in a computer. The PCIeIF 315 has a function that allows high-speed data transfer, for example, with a CPU, memories, and storages attached to an expansion card installed in a computer.

The EIF 316 is, for example, an interface having a function of connecting the solid state module 10, all devices (computers, printers, and the like) communicating via a network, and a network medium (cable).

The external IO may comprise, for example, the NI 317 and may be electrically connected to the R 318 via the NI 317. The external IO is electrically connected to the semiconductor cube 100 and an external circuit (not shown, for example, a power supply circuit, or the like) via the R 318, and has a function of transmitting and receiving signals to and from the external circuit and the semiconductor cube 100.

The memory controller 319 includes, for example, the NI 317. For example, the memory controller 319 is electrically connected to the R 318 via the NI 317. The memory controller 319 is connected to the semiconductor cube 100 through the R 318 and has a function of controlling the SRAM chip 110.

Each of the plurality of logic modules 211 has a function for controlling the transmission of signals (data) to the TCI-IO 212 or the reception of signals (data) from the TCI-IO 212. More specifically, it has functions for controlling the transmission of signals (data) to the semiconductor cube 100, the TCI router chip 300, the memory controller 319, the PCIeIF 315, the EIF 214, and a plurality of R 318, or the reception of signals (data) from the semiconductor cube 100, the TCI router chip 300, the memory controller 319, the PCIeIF 315, the EIF 214 and the plurality of R 318. Further, the logic module 211 also has the ability to drive the memory module 111 (see FIG. 9) within the SRAM chip 110. For example, the logic module 211 transmits a signal for driving the memory module 111 via the TCI-IO 212. The logic module 211 may include an arithmetic circuit such as, for example, a CPU (Central Processing Unit).

Each of the plurality of logic modules 211 more specifically has functions for controlling the transmission of signals (data) to the plurality of TCI-IOs 312 and the SRAM chips 110 in the semiconductor cube 100, the plurality of TCI-IOs 312, the DRAMIO 311, the PCIeIF 315, and the EIF 316 in the TCI router chip 300, the memory controller 319, and the plurality of Rs 318, or the reception of signals (data) from the plurality of TCI-IOs 312 and the SRAM chips 110 in the semiconductor cube 100, the plurality of TCI-IOs 312, the DRAMIO 311, the PCIeIF 315, and the EIF 316 in the TCI router chip 300, the memory controller 319, and the plurality of Rs 318.

As described above, each circuit in the TCI router chip 300 is connected in a network form via the network router (Router (R)), and each circuit in the semiconductor cube 100 and each circuit in the TCI router chip 300 are connected using inductor communication. The semiconductor module 10 is a so-called network-on-chip (Network on Chip (NoC)) in which the plurality of IP cores is connected in a network configuration, and is a module capable of communicable using the NoC and inductor communication.

For example, as shown in FIG. 4 or FIG. 5, a R 318h connected to the memory controller 319 is connected to a R 318g, a R 318e, and a R 318i in the TCI router chip 300. That is, the memory controller 319 connected to the R 318h is electrically connected to the DRAMIO 311 connected to the R 318g, the TCI-IO 312e connected to the R 318e, and to the EIF 316 connected to the R 318i through the signal bus 340. The TCI-IO 312e is connected with the logic chip 200 in the semiconductor cube 100 using the inductor 372. Specifically, the TCI-IO 312e communicates with the TCI-IO 212 via the inductor 372 and the inductor 272 and is connected to the logic chip 200 (logic module 211) and the SRAM chip 110 corresponding to the communicated inductor 272 (TCI-IO 212).

Thus, the memory controller 319 may send signals for driving the SRAM chip 110 to the TCI-IO 312e via the R 318h and the R 318e, and the TCI-IO 312e may communicate with the inductor 272 in the semiconductor cube 100 using the inductor 372 and transmit signals to the logic module 211 for driving the logic chip 200 (logic module 211) and the SRAM chip 110 corresponding to the communicated inductor 272 (TCI-IO 212).

The semiconductor module 10 includes the TCI router chip 300 in which routers connected to respective ones of the plurality of IP cores is connected in a network using a signal bus, and is capable of communicating using a network-type bus.

Further, the semiconductor module 10 can connect the TCI router chip 300 capable of communication using the network-type bus, the plurality of stacked sub-semiconductor cubes 101 including the logic chip 200 and the SRAM chip 110 which are brought into close proximity, and the semiconductor cube 100 vertically placed to the TCI router chip 300 using inductor communication. As a consequence, the semiconductor module 10 has excellent heat dissipation characteristics and can reduce power consumption, and connects each IP core, logic chip 200, and SRAM chip 110 within the TCI router chip 300 in three dimensions, thereby reducing signal transmission delays between each IP core, logic chip 200, and SRAM chip 110 within the TCI router chip 300.

### 1-2. Overview of Semiconductor Cube 100

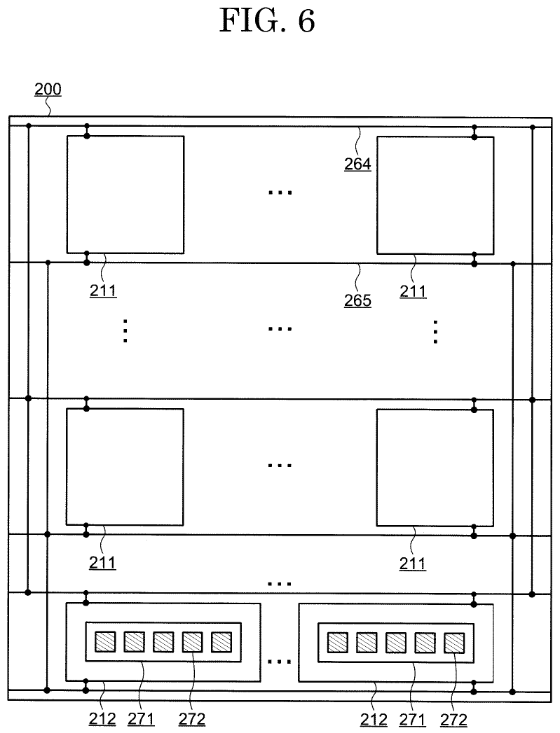

Next, an overview of the semiconductor cube 100 will be described referring to FIG. 1, FIG. 3A, and FIG. 6 to FIG. 11. FIG. 6 is a schematic diagram showing the configuration of the logic chip 200. FIG. 7 is a perspective view showing the configuration of the logic chip 200. FIG. 8 is a schematic cross-sectional view of the logic chip 200 taken along a line A1-A2 shown in FIG. 6. FIG. 9 is a schematic diagram showing the configuration of the SRAM chip 110. FIG. 10 is a perspective view showing the configuration of the SRAM chip. FIG. 11 is a sectional view showing a cross-sectional construction of the SRAM chip along a line B1-B2 shown in FIG. 9. Configurations that are the same as or similar to those in FIG. 1 to FIG. 5 will be described as necessary.

Referring to FIG. 1, as described in the section “1-1. Overview of Semiconductor Module 10,” the semiconductor cube 100 includes the sub-semiconductor cube 101 in which the logic chip 200 and the SRAM chip 110 electrically connected to the logic chip 200 are stacked in the direction D1. The second side surface 146 abuts against the adhesive layer 400 and is positioned to face the second surface 304 of the TCI router chip 300, with the semiconductor cube 100 arranged on the second surface 304 of the TCI router chip 300.

First, the configuration and functions of the logic chip 200 will be described with reference to FIG. 1, FIG. 3A, and FIG. 6 to FIG. 8. As shown in FIG. 6, the logic chip 200 includes the plurality of logic modules 211, the plurality of TCI-IOs 212, power supply wirings 264, and grounding wirings 265. Each of the plurality of TCI-IOs 212 includes the plurality of inductor groups 271, and the inductor group 271 includes the plurality of inductors 272.

The plurality of logic modules 211 and the plurality of TCI-IOs 212 are electrically connected to a power supply wiring 164 and a grounding wiring 165. The power supply wiring 164 and the grounding wiring 165 are electrically connected to an external circuit (not shown), for example, and are supplied with a power supply voltage VDD, a voltage VSS, and the like. The power supply VDD is, for example, 1 V, 3 V, or the like. The voltage VSS is, for example, a grounding voltage, 0 V, or the like.

As shown in FIG. 1 and FIG. 7, each of the plurality of logic chips 200 includes, for example, a transistor layer 230, a wiring layer 250, and the inductor layer 270. The plurality of logic chips 200 includes, for example, the logic chips 200n (see FIG. 3A) and the logic chips 200n+1 (see FIG. 3A) adjacent to the logic chips 200n.

As shown in FIG. 7, the logic chips 200 include the first surface 202 parallel to the direction D2 and the direction D3, and the second surface 204 opposed to the first surface 202 with respect to the direction D1. The first surface 202 is an exposed surface of the transistor layer 230. The second surface 204 is an exposed surface of the inductor layer 270. The first surface 202 and the second surface 204 are parallel to the first surface 142 and the second surface 144.

Further, the logic chip 200 also includes a first side surface 205 perpendicular to the first surface 202 and the second surface 204, a second side surface 206 adjacent to the first side surface 205, a third side surface 207 adjacent to the second side surface 206, and a fourth side surface 208 adjacent to the third side surface 207 and the first side surface 205. The first side surface 205 is part of the first side surface 145, the second side surface 206 is part of the second side surface 146, the third side surface 207 is part of the third side surface 147, and the fourth side surface 208 is part of the fourth side surface 148.

In addition, a portion of the power supply wiring 264 and a portion of the ground wiring 265 are exposed to, for example, the first side surface 205, the fourth side surface 208, or the third side surface 207, and are electrically connected to a side surface wiring electrically connected to the external circuit. The power supply voltage VDD and the voltage VSS are supplied to a portion of the power supply wiring 264 and the portion of the grounding wiring 265 through the external circuit and the side surface wiring. The side surface wiring can be formed by employing a technique used in the technical field of the semiconductor module.

As shown in FIG. 3A or FIG. 7, the inductor layer 270 includes the plurality of inductor groups 271. Each of the plurality of inductor groups 271 includes the plurality of inductors 272. The plurality of inductor groups 271 is arranged perpendicular to the directions D2 and D3 (that is, the first surface 202 and the second surface 204) and parallel to the direction D3. Each of the plurality of inductor groups 271 is arranged away from the fourth side 208 and proximate to the second side 206 (second side surface 146) and extend in the direction D2. Although the number of inductors 272 shown in FIG. 7 is three, the number of inductors 272 shown in FIG. 7 is an example. The number of inductors 272 can be changed as appropriate depending on the specifications and applications of the semiconductor module 10.

The plurality of inductors 272 includes, for example, an inductor having the function of data communication (data transmission), and an inductor having the function of clock communication (clock transmission). Each inductor 272 may perform inductor communication with the corresponding inductor 372 on a one-to-one basis in response to the clock received by clock communication (synchronously), and each inductor 272 may perform inductor communication with the corresponding inductor 372 on a one-to-one basis without synchronizing (asynchronously) to the clock received by clock communication. Also, for example, each inductor 272 may perform inductor communication with the corresponding inductor 372 asynchronously to clock communication on a one-to-one basis.

As shown in FIG. 8, the transistor layer 230 includes, for example, the substrate 273, a wiring 263, the through electrode 260, the through electrode 265, an insulating layer 274, a fin 267, a wiring 266, an activation region 284, a gate insulating film 275, a gate electrode 276, the N-type transistor 268, the P-type transistor 269, and an insulating layer 277. The substrate 273 is, for example, an N-type Si substrate or an N-type Si-wafer. As an example, the logic chip 200 is formed by a 2 nm CMOS process, and is formed using a fin-type transistor as shown in FIG. 8, but may be formed using a CMOS process other than 2 nm, or may be formed using a transistor other than a fin-type transistor. A structure of the transistor of the logic chip 200 may be appropriately selected according to the specifications, applications, and the like of the semiconductor module 10.

The through electrode 260, a through electrode 294, and a through electrode 295 are electrically connected to the wiring 263 which is a so-called embedded wiring, a portion of the through electrode 260, a portion of the through electrode 294 and a portion of the through electrode 295 are exposed to the first surface 202. The portion of the through electrode 260, the portion of the through electrode 294, and the portion of the through electrode 295 are electrically connected to the through electrode 160 exposed to the first surface 102 of the SRAM chip 110. Signals (data), power supply voltage VDD, voltage VSS, and the like are supplied to the through electrode 360, a through electrode 394, and a through electrode 395 from an external circuit via the logic chip 200 (for example, wiring 280).

The wiring layer 250 includes a multilayer wiring structure in which wirings and insulating layers are alternately stacked. The wiring layer 250 includes, for example, a wiring 278, an insulating layer 279, a wiring 280, and an insulating layer 281. The number of layers of the multilayer wiring in the wiring layer 250 is not limited to the two layers shown in FIG. 8. The number of layers of the multilayer wiring in the wiring layer 250 may be three or more. The number of layers of the multilayer wiring in the wiring layer 250 can be appropriately changed according to the specifications, applications, and the like of the semiconductor module 10.

The inductor layer 270 includes, for example, an insulating layer 282 and the plurality of inductors 272. The inductor layer 270 includes the plurality of inductor groups 271.

The wiring 263 is a so-called buried electrode. The wiring 278 and the wiring 266 are, for example, connected to an external circuit via the side surface wiring described above and the signal (data), the power supply voltage VDD, the voltage VSS, and the like are supplied to the wiring 263 via the side surface wiring, the wiring 278, and the wiring 266. The wiring 278 and the wiring 280 have, for example, a damascene structure, and the wiring 266 has, for example, a structure corresponding to a through electrode.

The inductor 272 is connected to the wiring 280, and the wiring 280 is connected to the wiring 278. Although not shown, the wiring 278 is electrically connected to a source electrode or a drain electrode of the N-type transistor 268, a source electrode or a drain electrode of the P-type transistor 269, and the gate electrode 276, and the like. The signal (data) received by the inductor 272 is transmitted to the N-type transistor 268, the P-type transistor 269, and the like via the wiring 280 and the wiring 278. The signal (data) including a result calculated by logical operation is transmitted to the inductor 272 via the N-type transistor 268, the P-type transistor 269, the wiring 280, and the wiring 278.

Referring now to FIG. 9 to FIG. 11, the configuration and functions of the SRAM chip 110 are described. As shown in FIG. 9, the SRAM chip 110 includes the plurality of logic modules 211, the power wiring 164, and the grounding wiring 165. Each of the plurality of logic modules 211 includes a memory cell array 115.

The memory module 111 has functions, for example, for generating a number of signals (data) to be transmitted, controlling a number of received signals (data) to store signals (data) in the memory cell array 115, reading signals (data) from the memory cell array 115, transmitting signals (data) to the logic chip 200, or receiving signals (data) from the logic chip 200.

The memory cell array 115 includes a plurality of memory cells (not shown). Each of a plurality of memory cell arrays 115 is, for example, a SRAM, and each of the plurality of memory cells is a SRAM cell. The SRAM, the SRAM cell, and the memory module 111 for the SRAM may employ techniques used in the art of the SRAM. Therefore, the detailed description will be omitted here.

The plurality of memory modules 111 are electrically connected to the power supply wiring 164 and the ground wiring 165. The power supply wiring 164 and the ground wiring 165, for example, are electrically connected to an external circuit (not shown), such as a power supply voltage VDD and the voltage VSS is supplied. The power supply VDD is, for example, 1 V, 3 V. The voltage VSS is, for example, a grounding voltage, 0 V, and the like.

As shown in FIG. 10, each of the plurality of SRAM chips 110 includes, for example, a transistor layer 130 and a wiring layer 150. Each of the plurality of SRAM chips 110 includes, for example, a SRAM chip 110n (not shown), and a SRAM chip 110n+1 (not shown) contiguous to the SRAM chip 110n.

As shown in FIG. 10, the SRAM chip 110 includes the first surface 102 parallel to the directions D2 and D3, and the second surface 104 opposing the first surface 102 with respect to the direction D1. The first surface 102 is the exposed surface of the transistor layer 130. The second surface 104 is an exposed surface of the wiring layer 150. The first surface 102 and the second surface 104 are parallel to the first surface 142 and the second surface 144.

Further, the SRAM chip 110 also includes a first side surface 105 perpendicular to the first surface 102 and second surface 104, a second side surface 106 adjacent the first side surface 105, a third side surface 107 adjacent the second side surface 106, and a fourth side surface 108 adjacent the third side surface 107 and the first side surface 105. The first side surface 105 is part of the first side surface 145, the second side surface 106 is part of the second side surface 146, the third side surface 107 is part of the third side surface 147, and the fourth side surface 108 is part of the fourth side surface 148.

In addition, the portion of the power supply wiring 164 and the portion of the ground wiring 165, for example, are exposed to the first side surface 105, the second side surface 106, or the third side surface 107, and are electrically connected to the side surface wiring which is electrically connected to the external circuit. The power supply voltage VDD and the voltage VSS are supplied to the portion of the power supply wiring 164 and the portion of the grounding wiring 165 through the external circuit and the side surface wiring. The side surface wiring can be formed employing techniques used in the art of semiconductor modules.

As shown in FIG. 11, the transistor layer 130 includes, for example, the substrate 173, a wiring 163, the through electrode 160, an insulating layer 174, a fin 167, a wiring 166, an activation region 184, a gate insulator 175, a gate electrode 176, the N-type transistor 168, the P-type transistor 169, and an insulating layer 177. The wiring layer 150 includes a multilayer wiring structure in which the wirings and the insulating layers are alternately stacked. The wiring layer 150 includes, for example, a wiring 178, an insulating layer 179, a wiring 180, an insulating layer 181, and an insulating layer 182.

Each configuration and function of the substrate 173, the wiring 163, the through electrode 160, the insulating layer 174, the fin 167, the wiring 166, the activation region 184, the gate insulating film 175, the gate electrode 176, the N-type transistor 168, the P-type transistor 169, the insulating layer 177, the wiring 178, the insulating layer 179, the wiring 180, the insulating layer 181, and the insulating layer 182 are the same as each configuration and function of the substrate 273, the wiring 263, the through electrode 260, the insulating layer 274, the fin 267, the wiring 266, the activation region 284, the gate insulating film 275, the gate electrode 276, the N-type transistor 268, the P-type transistor 269, the insulating layer 277, the wiring 278, the insulating layer 279, the wiring 280, the insulating layer 281, and the insulating layer 282 described in the configuration and the function of the logic chip 200 of the section “1-2. Overview of Semiconductor Cube 100”. Therefore, each layer and wiring constituting the transistor layer 130, the wiring layer 150, and the like will be described as necessary.

The through electrode 160 electrically connected to the wiring 163 is a so-called embedded electrode. A portion of the through electrode 160 is exposed to the first surface 102. The portion of the through electrode 160 is electrically connected to the through electrode 260, the through electrode 294, or the through electrode 295, which is exposed on the first surface 202 of the logic chip 200. The wiring 178 and the wiring 166, for example, are connected to an external circuit via the side surface wiring described above, a signal (data), the power supply voltage VDD, the voltage VSS, and the like are supplied to the wiring 163 through the side surface wiring, the wiring 178, and the wiring 166. The wiring 178 and the wiring 180 have, for example, a damascene structure, and the wiring 166 has, for example, a structure corresponding to the through electrode.

### 1-3. Overview of TCI Router Chip 300

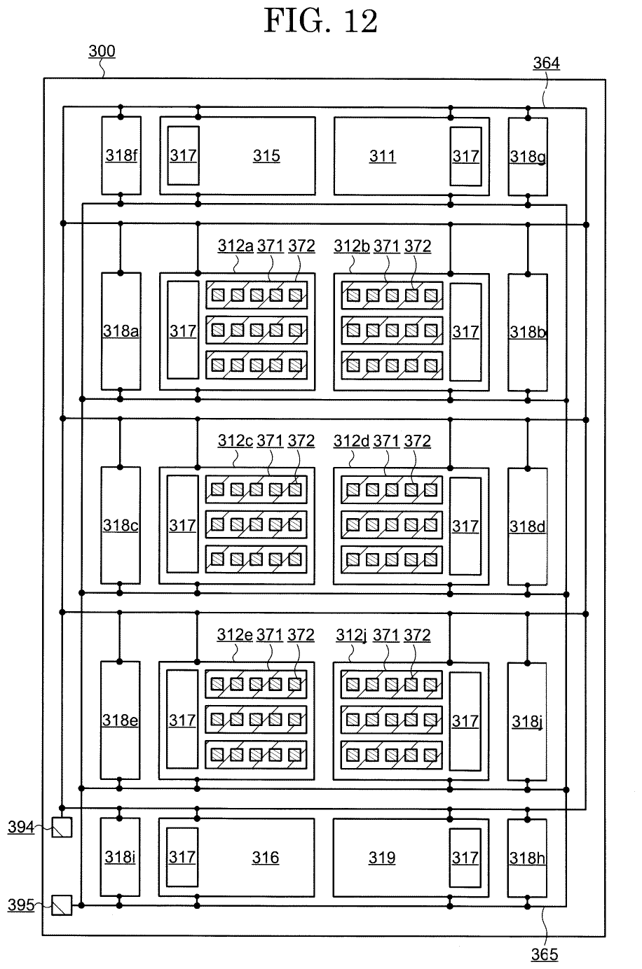

Next, an overview of the TCI router chip 300 will be described referring to FIG. 1, FIG. 3A, and FIG. 12 to FIG. 14. FIG. 12 is a diagram showing a configuration of the TCI router chip 300. FIG. 13 is a perspective view showing a configuration of the TCI router chip 300. FIG. 14 is a cross-sectional view schematically showing a cross-sectional configuration of the TCI router chip 300 along a line C1-C2 shown in FIG. 13. The same or similar configurations as those in FIG. 1 to FIG. 11 will be described as necessary.

Referring to FIG. 1, as described in the section “1-1. Overview of Semiconductor Module 10”, the TCI router chip 300 includes a configuration in which the transistor layer 330, the wiring layer 350, and the inductor layer 370 are stacked in this order in the direction D3, and includes the first surface 302 parallel to the direction D1 and the direction D2, and the second surface 304 opposite to the first surface 302. The first surface 302 is an exposed surface of the transistor layer 330. The second surface 304 is an exposed surface of the inductor layer 370.

As shown in FIG. 1 and FIG. 10, the inductor layer 370 includes a plurality of inductor groups 371 (See FIG. 1.). The plurality of inductor groups 371 (for example, see FIG. 3A) includes the plurality of inductors 372. The plurality of inductors 372 is arranged in a matrix parallel to the directions D1 and D2 (that is, the first surface 302 and the second surface 304).

As shown in FIG. 14, the transistor layer 330 includes, for example, the substrate 373, a wiring 363, the through electrode 360, the through electrode 394, the through electrode 395, an insulating layer 374, a fin 367, a wiring 366, an activation region 384, a gate insulating film 375, a gate electrode 376, the N-type transistor 368, the P-type transistor 369, and an insulating layer 377. The wiring layer 350 includes a multilayer wiring structure in which wirings and insulating layers are alternately stacked. The wiring layer 350 includes, for example, a wiring 378, an insulating layer 379, a wiring 380, and an insulating layer 381. The inductor layer 370 includes, for example, an insulating layer 382 and the plurality of inductors 372.

The configuration and the function of each of the substrate 373, the wiring 363, the insulating layer 374, the fin 367, the wiring 366, the activation region 384, the gate insulating film 375, the gate electrode 376, the N-type transistor 368, the P-type transistor 369, the insulating layer 377, the wiring 378, the insulating layer 379, the wiring 380, the insulating layer 381, the insulating layer 382, and the inductor 372 are the same as the configuration and the function of each of the substrate 173, the wiring 163, the insulating layer 174, the fin 167, the wiring 166, the activation region 184, the gate insulating film 175, the gate electrode 176, the N-type transistor 168, the P-type transistor 169, the insulating layer 177, and the wiring 178, the insulating layer 179, the wiring 180, the insulating layer 181, the insulating layer 182, and an inductor 172 described in the section “1-2. Overview of Semiconductor Cube 100”. Therefore, each layer and wiring constituting the transistor layer 330, the wiring layer 350, and the inductor layer 370 will be described as necessary.

The through electrode 360, the through electrode 394, and the through electrode 395 are electrically connected to the wiring 363 that is a so-called buried wiring, and a portion of the through electrode 360, a portion of the through electrode 394, and a portion of the through electrode 395 are exposed to the first surface 302. The portion of the through electrode 360, the portion of the through electrode 394, and the portion of the through electrode 395 are electrically connected to the through electrode 609 exposed on the first surface 602 of the package substrate 600 via the bump 502 of the bump layer 500. A signal (data), the power supply voltage VDD, the voltage VSS, and the like are supplied from the external circuit to the through electrode 360, the through electrode 394, and the through electrode 395 via the bump layer 700, the package substrate 600 and the bump layer 500.

Referring to FIG. 4 and FIG. 5, as described in the section “1-1-3. Circuit Configuration of Semiconductor Module 10”, as shown in FIG. 12, the TCI router chip 300 includes, for example, the plurality of TCI-IOs 312, the plurality of Rs 318, DRAMIO 311, the PCIeIF 315, the EIF 316, and the memory controller 319. In addition, the plurality of TCI-IOs 312 includes the TCI-IOs 312a to 312e and a TCI-IO 312j, and the plurality of Rs 318 includes the R 318a to a R 318j. Each of the plurality of TCI-IOs 312 includes the plurality of inductor groups 371, and the inductor group 371 includes the plurality of inductors 372. In addition, the configuration of the TCI router chip 300 shown in FIG. 12 is an example, and the configuration of the TCI router chip 300 is not limited to the example shown in FIG. 12. For example, the TCI router chip 300 may include IP cores other than those shown in FIG. 12.

As an example, a power supply wiring 364 is electrically connected to the through electrode 394, a ground wiring 365 is electrically connected to the through electrode 395, and the signal bus 340 is electrically connected to the through electrode 360. As shown in FIG. 12, the TCI router chip 300 includes one through electrode 394 and one through electrode 395, and includes one system of power supply wiring 364 and one system of grounding wiring 365. Further, as shown in FIG. 14 or FIG. 5, the TCI router chip 300 includes two through electrodes 360 as one example and includes three systems of signal buses 340. The number of the through electrodes 394, the through electrodes 395, and the through electrodes 360 included in the TCI router chip 300 and the number of the power supply wirings 364, the grounding wirings 365, and the signal buses 340 are not limited to those shown in FIG. 14 or FIG. 5. The TCI router chip 300 may include two or more through electrodes 394, through electrodes 395, and through electrodes 360, and may include two or more power supply wirings 364, grounding wirings 365, and signal buses 340. The number of the through electrodes 394, the through electrodes 395, and the through electrodes 360 included in the TCI router chip 300 and the number of systems of the power supply wirings 364, the grounding wirings 365, and the signal bus 340 can be changed as appropriate depending on the specifications, applications, and the like of the semiconductor module 10.

As shown in FIG. 3A or FIG. 13, the plurality of inductors 372 is arranged in a matrix in the direction D1 and the direction D2 on the second surface 304 side. Similar to the plurality of inductors 172, the plurality of inductors 372 includes, for example, an inductor having a function of data communication (data transmission) and an inductor having a function of clock communication (clock transmission). Similar to each inductor 172, each inductor 372 may perform inductor communication with the corresponding inductor 172 on a one-to-one basis depending on the clock received by clock communication (synchronously), and may perform inductor communication with the corresponding inductor 172 on a one-to-one basis without synchronizing (asynchronously) with the clock received by clock communication.

As described above, the semiconductor module 10 includes the TCI router chip 300. The TCI router chip 300 serves as a router for networking various IP cores including the logic chip 200, and the memory chip (SRAM chip 110, DRAM chip 110A, NVM chip 110B, SRAM chip 110C, and DRAM chip 110D described below). The semiconductor module 10, which includes the TCI router chip 300, can package a plurality of IP cores, which have conventionally been mounted in parallel on a package substrate, into a single package. As a result, the semiconductor module 10 can suppress delays in signal transmission and increases in power consumption of the chips due to a length of a wiring or a wiring load (capacitance). That is, the semiconductor module 10 is a module that can reduce the delay of the signal transmission and power consumption.

Also, since the TCI router chip 300 included in the semiconductor module 10 includes the SRAM chip, the DRAM chip, the memory controller, and various communication interfaces included in the semiconductor module 10, so each of the plurality of logic chips 200 does not need to include IP cores related to communication interfaces such as the PCIeIF and the EIF. For example, in the case where a conventional semiconductor module that does not include the TCI router chip 300 includes four logic chips, there is a problem that since each of the four logic chips includes an IP core associated with the communication interface, an area of the semiconductor module is large, and manufacturing costs of the semiconductor module is high. On the other hand, in the case where the semiconductor module 10 includes four logic chips, the four logic chips share the TCI router chip 300, and each of the four logic chips are selectively connectable with a communication interface. As a result, the semiconductor module 10 can be made smaller in area and at lower manufacturing costs than a conventional semiconductor module.

### Second Embodiment

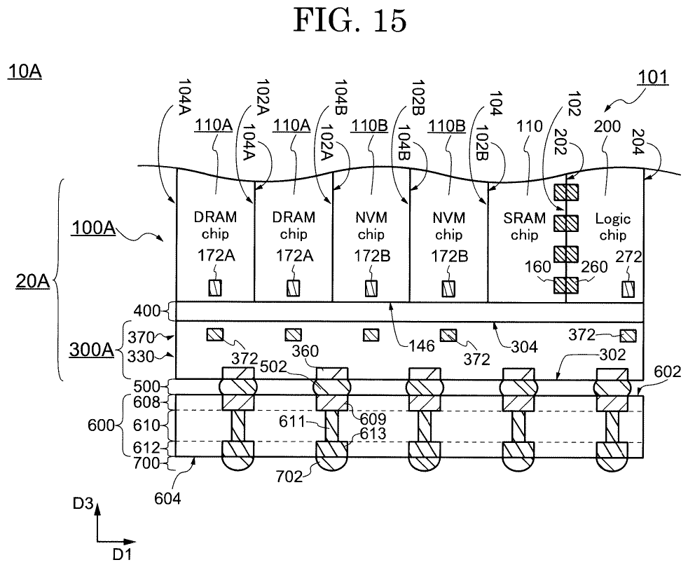

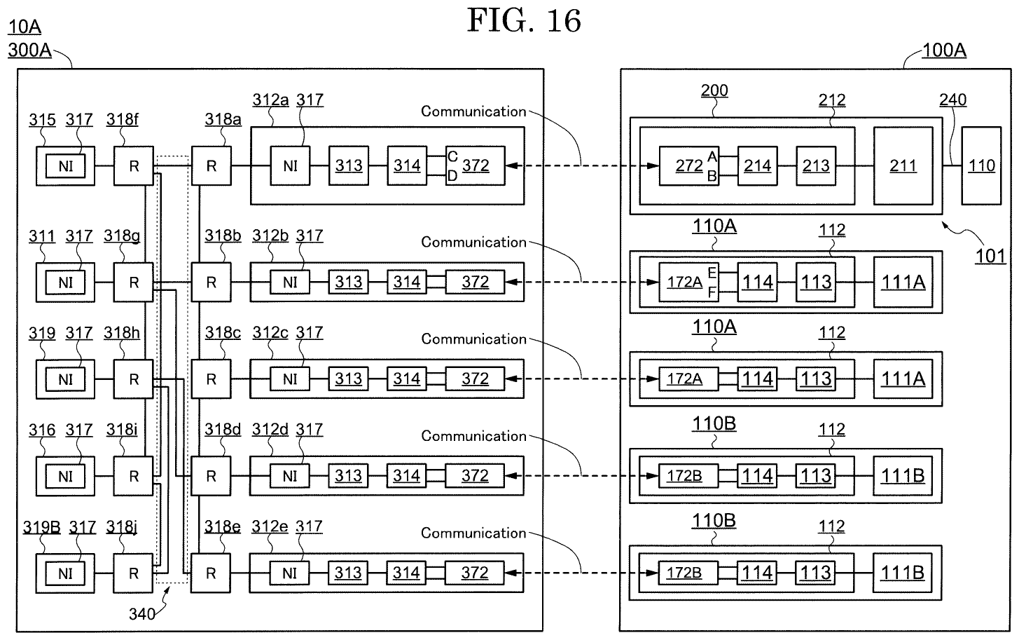

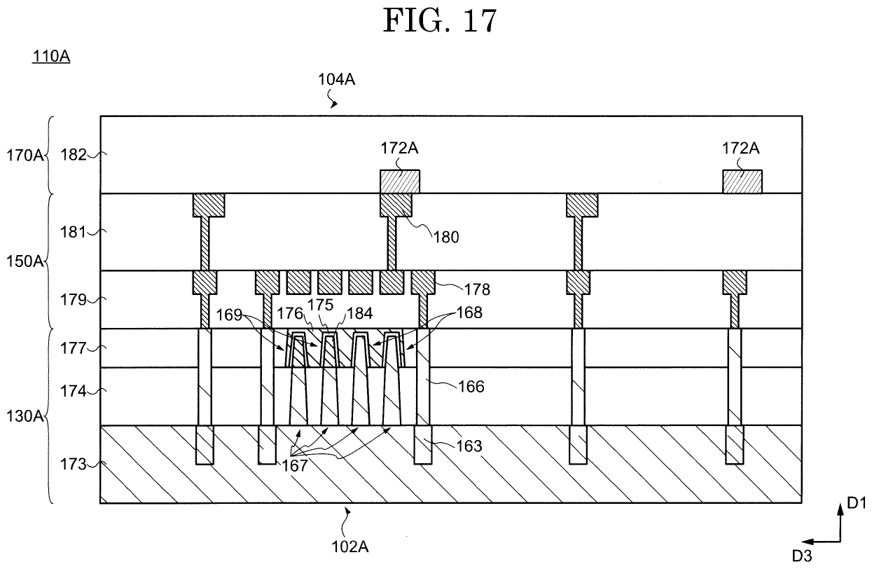

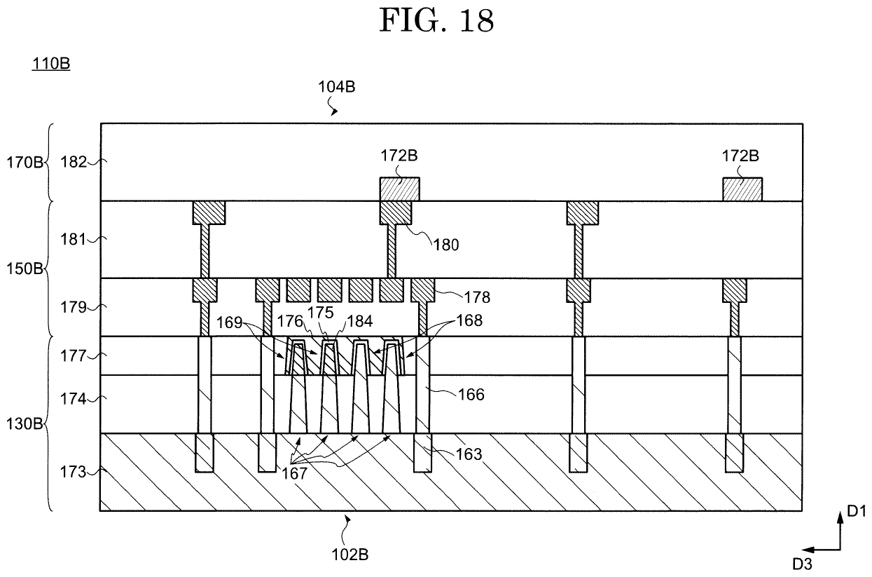

A semiconductor module 10A according to a second embodiment will be described referring to FIG. 12, and FIG. 15 to FIG. 18. FIG. 15 is a cross-sectional view schematically showing a configuration of the semiconductor module 10A. FIG. 16 is a schematic diagram showing configurations of a semiconductor cube 100A and a TCI router chip 300A included in the semiconductor module 10A. FIG. 17 is a cross-sectional view schematically showing a cross-sectional configuration of the DRAM chip 110A. FIG. 18 is a cross-sectional view schematically showing a cross-sectional configuration of the NVM chip 110B. Configurations that are the same as or similar to those in FIG. 1 to FIG. 14 will be described as necessary.

First, an overview of the semiconductor module 10A will be described with reference to FIG. 12, FIG. 15, and FIG. 16.

As shown in FIG. 15, the semiconductor module 10A includes the semiconductor cube 100A, the TCI router chip 300A, and the adhesive layer 400. For example, a stacked body 20A is composed of the semiconductor cube 100A, the TCI router chip 300A, and the adhesive layer 400. The semiconductor module 10A may include the bump layer 500, the package substrate 600, and the bump layer 700. The semiconductor module 10A includes a configuration in which the semiconductor cube 100 and the TCI router chip 300 of the semiconductor module 10 are replaced with the semiconductor cube 100A and the TCI router chip 300A. Configurations other than the semiconductor cube 100A and the TCI router chip 300A of the semiconductor module 10A are the same as those of the semiconductor module 10. In the explanation of the semiconductor module 10A, the same configuration as that of the semiconductor module 10 will be explained as needed.

The semiconductor cube 100A includes the sub-semiconductor cube 101, a plurality of DRAM chips 110A, and a plurality of NVM (Non Volatile Memory) chips 110B. The sub-semiconductor cube 101 has the configuration and functions described in the section “1-1-1. Overview of Semiconductor Module 10,” the section “1-1-2. Overview of Inductor 272 and Inductor 372,” the section “1-1-3. Circuit Configuration of Semiconductor Module 10,” and the section “1-2. Overview of Semiconductor Cube 100”and will be described as necessary.

Each of the plurality of DRAM chips 110A has the same configuration including a first surface 102A which is an exposed surface of the DRAM chip 110A, a second surface 104A which is an exposed surface of the DRAM chip 110A and the opposing the first surface 102A, and a plurality of inductors 172A (third inductor). The plurality of DRAM chips 110A includes two DRAM chips 110A, the second surface 104A of one DRAM chip 110A and the first surface 102A of the other DRAM chip 110A are joined using fusion bonding.

Each of the plurality of NVM chips 110B has the same configuration including a first surface 102B which is an exposed surface of the NVM chip 110B, a second surface 104B which is an exposed surface of the NVM chip 110B and the opposing first surface 102B, and a plurality of inductors 172B (third inductor). The plurality of NVM chips 110B includes, as an example, two NVM chips 110B, the second surface 104B of one NVM chip and the first surface 102B of the other NVM chip 110B are joined using fusion bonding.

The sub-semiconductor cube 101, the plurality of NVM chips 110B, and the plurality of DRAM chips 110A are stacked in this order in the direction D1. More specifically, the second surface 104 of the SRAM chip 110 and the first surface 102B of the NVM chip 110B are bonded using fusion bonding, and the second surface 104B of the other NVM chip 110B and the first surface 102B of one DRAM chip 110A are bonded using fusion bonding.

In addition, the number of the sub-semiconductor cubes 101, the plurality of NVM chips 110B, the plurality of DRAM chips 110A, the order of stacking, and the surface to be bonded shown in the semiconductor cube 100A, and the like are examples, but are not limited to the example shown here. The number of sub-semiconductor cubes 101 and the number of each chip, the order of stacking, and the surface to be bonded can be appropriately changed depending on the specifications, the application, or the like of the semiconductor module 10A.

As shown in FIG. 16, the DRAM chip 110A includes a plurality of TCI-IOs 112 and a plurality of DRAM modules 111A. The plurality of TCI-IOs 112 included in the DRAM chip 110A is electrically connected to the DRAM module 111A. Although the DRAM chip 110A includes the plurality of TCI-IOs 112, in FIG. 16, the number of TCI-IOs 112 in the DRAM chip 110A is reduced to one for clarity of the drawings.

The TCI-IO 112 included in the DRAM chip 110A includes the inductor 172A, a transmission/reception circuit 114, and a parallel-series conversion circuit 113. The inductor 172A is electrically connected to the transceiver/reception circuit 114 using a terminal E and a terminal F. The transmission/reception circuit 114 is electrically connected to the parallel-series conversion circuit 113. The parallel-serial conversion circuit 113 is electrically connected to the DRAM module 111A.

Although not shown, the DRAM module 111A includes memory cell arrays as well as the logic module 111. The memory cell arrays included in the DRAM module 111A are DRAM that include a plurality of DRAM cells. The DRAM module 111A may employ techniques used in the art of the DRAM. Therefore, the detailed description will be omitted here.

The DRAM module 111A has functions for controlling, for example, a number of signals (data) including a received program and storing signals (data) in the memory cell array, reading a number of signals (data) including the program from the memory cell array, transmitting a number of signals (data) including the program to the logic chip 200, or receiving the signal (data) from the logic chip 200.

The inductor 172A has the same functions and configuration as the inductor 272. The inductor 172A has the ability to inductively communicate with the inductor 372 of the TCI router chip 300 in a non-contact manner.

Further, as shown in FIG. 16, the NVM chip 110B includes the plurality of TCI-IOs 112 and a plurality of NVM modules 111B. The plurality of TCI-IOs 112 (parallel-series conversion circuit 113) included in the NVM chip 110B is electrically connected to the NVM module 111B. Similar to the DRAM chip 110A, although the NVM chip 110B includes the plurality of TCI-IOs 112, in FIG. 16, the number of the TCI-IO 112 in the NVM chip 110B is reduced to one for clarity of the drawings.

Since the TCI-IO 112 included in the NVM chip 110B has the same configuration and function as the TCI-IO 112 included in the DRAM chip 110A, it will be described as required. Further, in order to distinguish from the inductor 172B included in the DRAM chip 110A, although the inductor 172B included in the NVM chip 110B is labeled with a different reference sign from the inductor 172A, the configuration and function of the inductor 172B is similar to the configuration and function of the inductor 172A, and will be described as required.

Although not shown, the NVM module 111B includes memory cell arrays as well as logic modules 111. The memory cell arrays included in the NVM module 111B are NVM that include a plurality of NVM cells. The NVM module 111B may employ techniques used in the art of the NVM. Therefore, the detailed description will be omitted here.

The NVM module 111B includes, for example, a function of reading a number of signals (data) from a memory cell array and transmitting a number of signals (data), and a function of storing a number of received signals in the memory cell array.

The inductor 172A has the same functions and configuration as the inductor 272. The inductor 172A has the ability to inductively communicate with the inductor 372 of the TCI router chip 300 in a non-contact manner.

The TCI router chip 300A includes a configuration of the TCI router chip 300 with the addition of an NVM controller 319B and the R 318j. Configurations other than the configuration of adding the NVM controller 319B and the R 318j of the TCI router chip 300A are the same as the semiconductor module 10. The NVM controller 319B is electrically connected to the R 318j. The R 318j is electrically connected to the R 318i and the R 318h using, for example, the plurality of signal buses 340. The NVM controller 319B and the R 318j are IP cores, for example.

The NVM controller 319B, similar to the memory controller 319, includes the NI 317. In addition, the NVM controller 319B may not include the NI 317, the NI 317 may be located outside the NVM controller 319B, and the NVM controller 319B may be electrically connected to the R 318 via the NI 317.

The NVM controller 319B is connected to the logic module 211 via the R 318j, the TCI-IO 312 (inductor 372), and the TCI-IO 112 (inductor 272). Further, the NVM controller 319B is also connected to the NVM module 111B via the R 318j, the TCI-IO 312 (inductor 372), and the TCI-IO 112 (inductor 172B). That is, the NVM controller 319B has a function of transmitting and receiving signals to and from the logic module 211 and the NVM module 111B using inductor communication.

The memory controller 319 of the semiconductor module 10A includes, for example, functions for controlling the SRAM chip 110 and functions for controlling the DRAM. The memory controller 319 may be connected to the R 318g connected to the DRAMIO 311 via the R 318h. The memory controller 319 is connected to the logic module 211 via the R 318h, the R 318g, the DRAMIO 311, the TCI-IO 312 (inductor 372), and the TCI-IO 212 (inductor 272). The memory controller 319 is also connected to the DRAM module 111A via the R 318h, the R 318g, the DRAMIO 311, the TCI-IO 312 (inductor 372), and the TCI-IO 212 (inductor 272). That is, the memory controller 319 has a function of transmitting and receiving signals to and from the logic module 211 and the DRAM module 111A using inductor communication.

The semiconductor module 10A can achieve the same advantages as the semiconductor module 10. The semiconductor module 10A is superior to conventional semiconductor modules in thermal conductivity and heat removal properties, and it is possible to perform low power consumption and high speed non-volatile storage of signal transmission and large-capacity signals (data) including a program of large capacity.

In addition, as shown in FIG. 12, the plurality of TCI-IOs 312 includes the plurality of inductors 372. The plurality of inductors 372 may be arranged in groups, each group including an inductor in communication with the logic chip 200, an inductor in communication with the NVM chip 110B, and an inductor in communication with the DRAM chip 110A. Specifically, the plurality of inductors 372 included in the TCI-IO 312a for communicating with the logic chip 200 is arranged collectively, the plurality of inductors 372 included in the TCI-IOs 312d and 312e for communicating with the NVM chip 110B are arranged collectively, and the plurality of inductors 372 included in the TCI-IOs 312b and 312c for communicating with the DRAM chip 110A may be arranged collectively. By arranging the inductors for communication together for each type of chip, inductor communication between the logic chip and the same type of memory chip (SRAM chip, DRAM chip, NVM chip, etc.) can be transmitted at a higher speed.

Next, referring to FIG. 17 and FIG. 18, a schematic of cross-sectional constructions of the DRAM chip 110A and the NVM chip 110B will be described.

As shown in FIG. 17, the DRAM chip 110A includes the first surface 102A which is parallel to the directions D2 and D3, and the second surface 104A which is opposite the first surface 102A with respect to the direction D1. The first surface 102A is an exposed surface of a transistor layer 130A. The second surface 104A is an exposed surface of the inductor layer 170A. The first surface 102A and the second surface 104A are parallel to a first surface 142A and a second surface 144A.

The DRAM chip 110A includes the transistor layer 130A, an interconnect layer 150A, and the inductor layer 170A.

The transistor layer 130A does not include the through electrode 160 as compared to the transistor layer 130. That is, the transistor layer 130A includes the substrate 173, the wiring 163, the insulating layer 174, the fin 167, the wiring 166, the activation region 184, the gate insulator 175, the gate electrode 176, the N-type transistor 168, the P-type transistor 169, and the insulating layer 177.

The wiring layer 150A does not include the insulating layer 182 as compared to the wiring layer 150. That is, the wiring layer 150A includes the wiring 178, the insulating layer 179, the wiring 180, and the insulating layer 181.

The inductor layer 170A includes the insulating layer 182 and the inductor 172A.

As shown in FIG. 18, the NVM chip 110B includes the first surface 102B which is parallel to the direction D2 and the direction D3, and the second surface 104B which is opposite to the first surface 102B with respect to the direction D1. The first surface 102B is an exposed surface of a transistor layer 130B. The second surface 104B is an exposed surface of an inductor layer 170B. The first surface 102B and the second surface 104B are parallel to the first surface 142A and the second surface 144A.

The NVM chip 110B includes the transistor layer 130B, an interconnect layer 150B, and the inductor layer 170B.

The transistor layer 130B does not include the through electrode 160 as compared to the transistor layer 130. That is, the transistor layer 130B includes the substrate 173, the wiring 163, the insulating layer 174, the fin 167, the wiring 166, the activation region 184, the gate insulator 175, the gate electrode 176, the N-type transistor 168, the P-type transistor 169, and the insulating layer 177.

The wiring layer 150B does not include the insulating layer 182 as compared to the wiring layer 150. That is, the wiring layer 150B includes the wiring 178, the insulating layer 179, the wiring 180, and the insulating layer 181.

The inductor layer 170B includes the insulating layer 182 and the inductor 172B.

### Third Embodiment

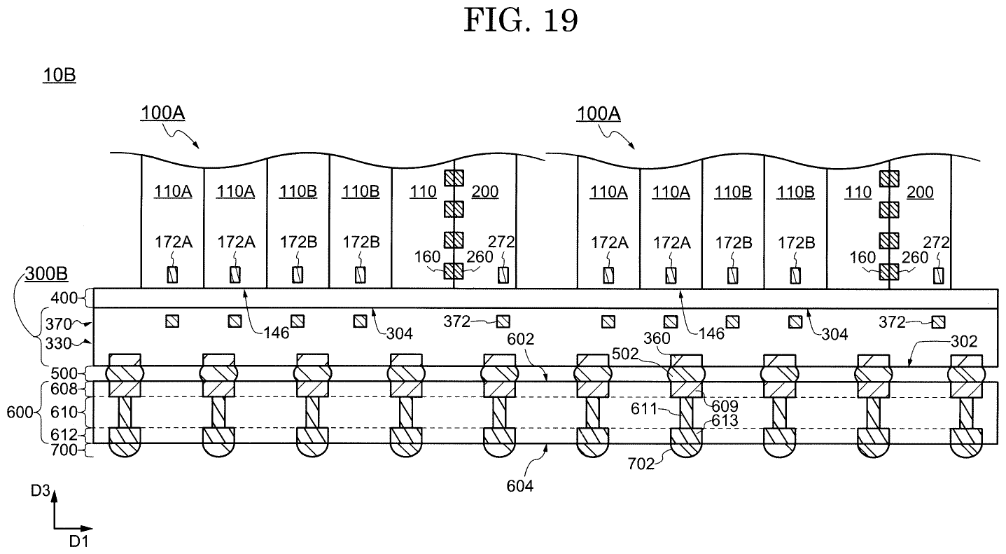

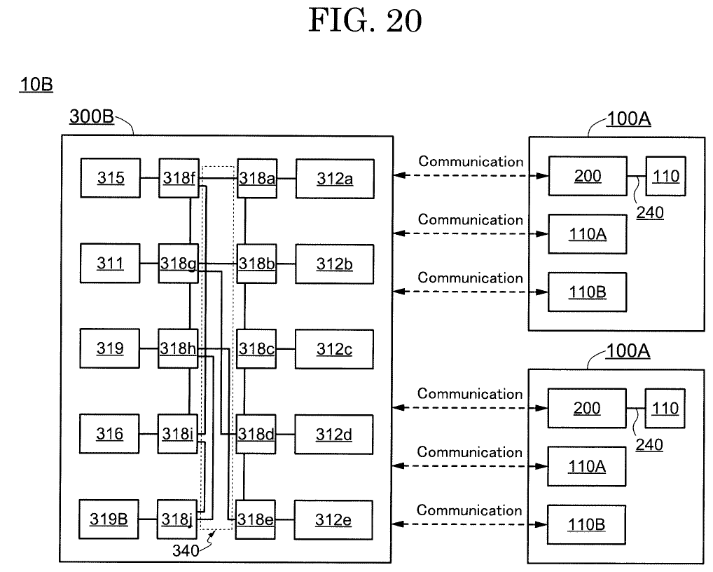

A semiconductor module 10B according to a third embodiment will be described referring to FIG. 19 and FIG. 20. FIG. 19 is a cross-sectional view showing an overview of a configuration of the semiconductor module 10B. FIG. 20 is a schematic diagram showing a configuration of the semiconductor cube 100A and a TCI router chip 300B included in the semiconductor module 10B. Configurations that are the same as or similar to those in FIG. 1 to FIG. 18 will be described as necessary.

As shown in FIG. 19, the semiconductor module 10B includes two semiconductor cubes 100A, the TCI router chip 300B and the adhesive layers 400. The semiconductor module 10B may include the bump layer 500, the package substrate 600, and the bump layer 700. The semiconductor module 10B includes one more semiconductor cube 100A than the semiconductor module 10A. The semiconductor module 10B has the same configuration as the semiconductor module 10A, except that it includes one more semiconductor cube 100A. The same configuration as that of the semiconductor module 10 will be explained as needed in the explanation of the semiconductor module 10B.

The two semiconducting cubes 100A are spaced apart in the direction D1, connected to the adhesive layer 400, and arranged on the second surface 304 of the TCI router chip 300B.

The TCI router chip 300B includes the plurality of inductors 372. The plurality of inductors 372 is arranged at positions corresponding to the respective inductors 172A, 172B, and 272 included in the two semiconductor cubes 100A. The configuration and function of the TCI router chip 300B is similar to the configuration and function of the TCI router chip 300A except that it includes an inductor corresponding to the inductor of each of the two semiconductor cubes 100A.

As shown in FIG. 20, the TCI router chip 300B is configured for inductive communication with two semiconductor cubes 100A. Although the semiconductor module 10B includes two semiconductor cubes 100A as an example, the number of semiconductor cubes 100A included in the semiconductor module 10B is not limited to two. The number of semiconductor cubes 100A included in the semiconductor module 10B may be three or more. The number of the semiconductor modules 100A included in the semiconductor cube 10B can be changed as appropriate depending on the specifics, applications, or the like of the semiconductor module 10B.

The semiconductor module 10B can achieve the same advantages as the semiconductor module 10. Further, by including the two semiconductor cubes 100A, the semiconductor module 10B can comprise two logic chips 200 and various memory chips, so-called functions of a multi-core. The semiconductor module 10B is superior to the conventional semiconductor module in thermal conductivity and heat removal properties, it is possible to process at least two programs in parallel with low power consumption, and data processing with low power consumption can be performed at high speed.

### Fourth Embodiment

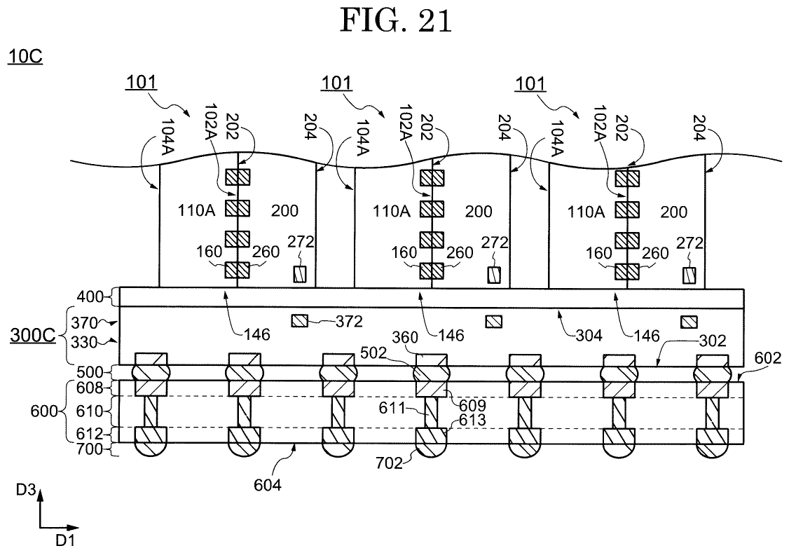

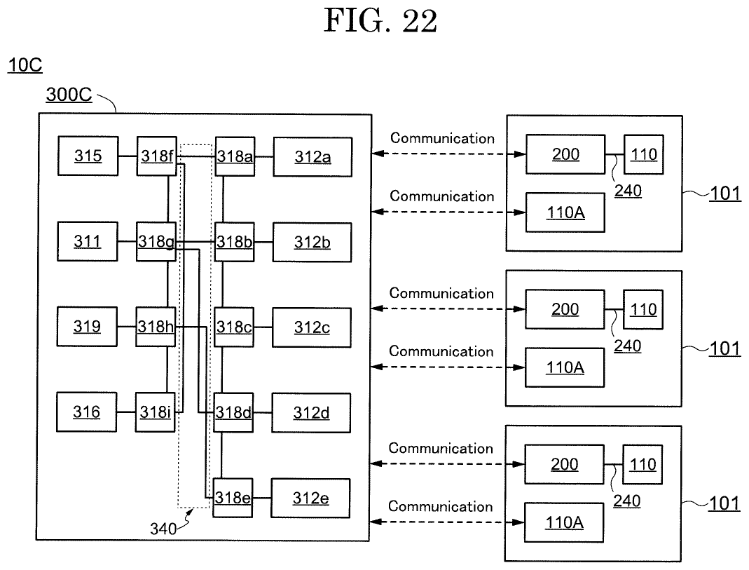

A semiconductor module 10C according to a fourth embodiment will be described referring to FIG. 21 and FIG. 22. FIG. 21 is a cross-sectional view showing an overview of a configuration of the semiconductor module 10C. FIG. 22 is a schematic diagram showing a configuration of the sub-semiconductor cube 101 and a TCI router chip 300C included in the semiconductor module 10C. Configurations that are the same as or similar to those in FIG. 1 to FIG. 20 will be described as necessary.

As shown in FIG. 21, the semiconductor module 10C includes three sub-semiconductor cubes 101, the TCI router chip 300C, and the adhesive layer 400. The semiconductor module 10C may include the bump layer 500, the package substrate 600, and the bump layer 700. The semiconductor module 10C includes a configuration in which the plurality of sub-semiconductor cubes 101 in the semiconductor cube 100 are spaced from each other with respect to the semiconductor module 10. A configuration other than the semiconductor module 10C including a configuration in which the plurality of sub-semiconductor cubes 101 are spaced apart from each other is the same as the semiconductor module 10. The same configuration as the semiconductor module 10 will be described as required in the description of the semiconductor module 10C.

Three sub-semiconductor cubes 101 are spaced apart in the direction D1 and connected to the adhesive layer 400 and arranged on the second surface 304 of the TCI router chip 300C.

The TCI router chip 300C includes the plurality of inductors 372. The plurality of inductors 372 is arranged at positions corresponding to respective inductors 272 included in the three sub-semiconductor cubes 101. The configuration and function of the TCI router chip 300C is similar to the configuration and function of the TCI router chip 300 except that it includes the inductor 372 corresponding to the respective inductor 272 included in the three sub-semiconductor cubes 101.

As shown in FIG. 22, the TCI router chip 300C includes a similar configuration and function as the TCI router chip 300 and is configured to be in inductive communication with each of the three sub-semiconductor cubes 101. Although the semiconductor module 10C includes the three sub-semiconductor cubes 101 as an example, the number of the sub-semiconductor cubes 101 including the semiconductor module 10C is not limited to three. The number of the sub-semiconductor cubes 101 included in the semiconductor module 10C may be two or more. The number of the sub-semiconductor cubes 101 including the semiconductor module 10C can be changed as appropriate depending on the specifics, applications, or the like of the semiconductor module 10C.

The semiconductor module 10C can achieve the same advantages as the semiconductor module 10. Further, by three sub-semiconductor cubes 101 being spaced apart from each other, for example, it is possible to increase the surface area of the semiconductor cube in the semiconductor module 10C. Consequently, the semiconductor module 10C is superior to, for example, conventional semiconductor modules due to thermal conductivity and heat removal properties.

### Fifth Embodiment

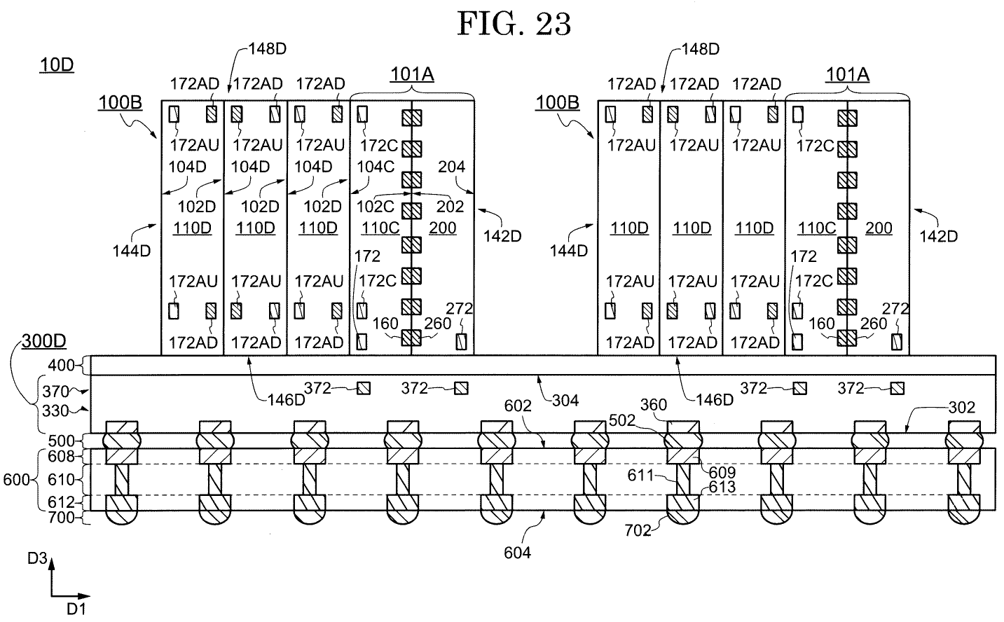

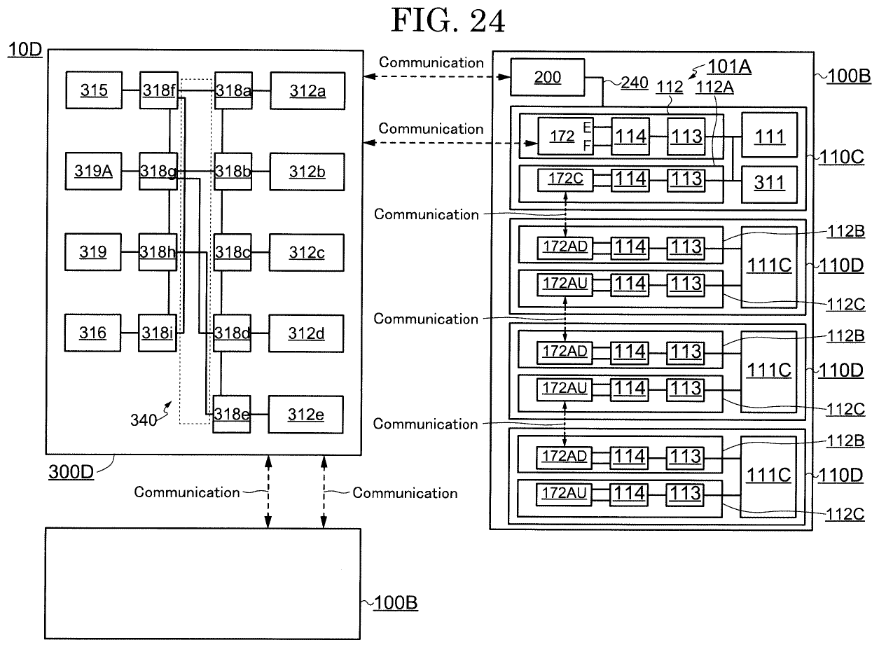

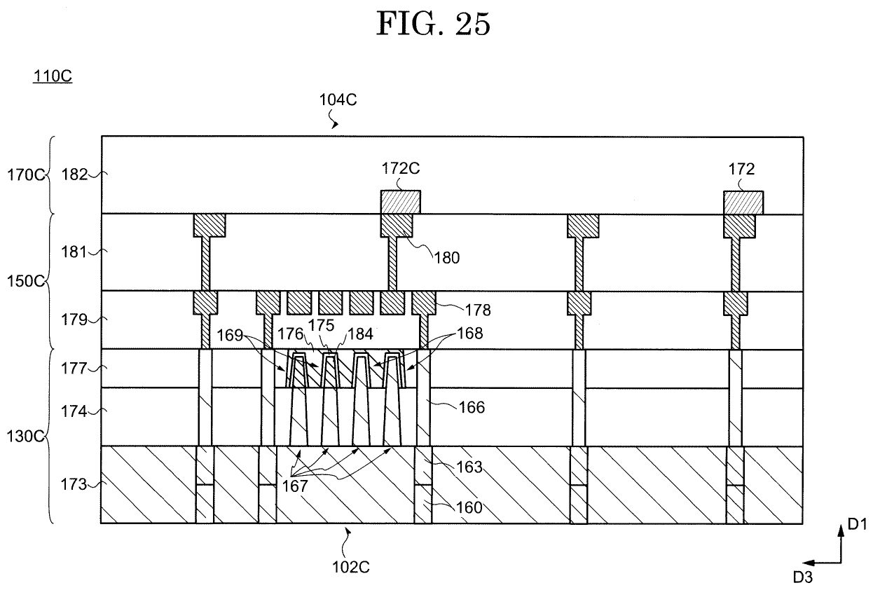

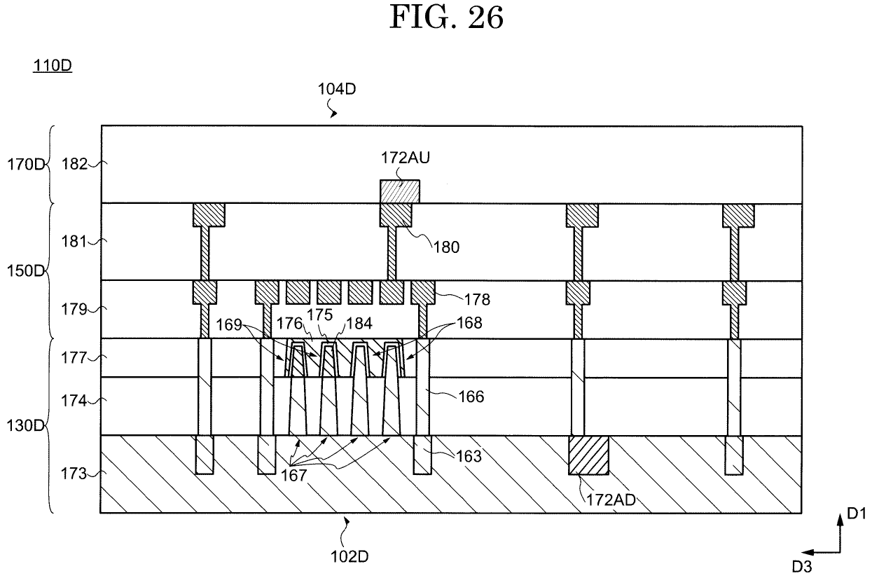

A semiconductor module 10D according to a fifth embodiment will be described referring to FIG. 23 to FIG. 26. FIG. 23 is a cross-sectional view showing an overview of a configuration of the semiconductor module 10D. FIG. 24 is a schematic diagram showing configurations of a semiconductor cube 100B and the TCI router chip 300D included in the semiconductor module 10D. FIG. 25 is a cross-sectional view schematically showing a cross-sectional configuration of a SRAM chip 110C. FIG. 26 is a cross-sectional view schematically showing a cross-sectional configuration of a DRAM chip 110D. Configurations that are the same as or similar to those in FIG. 1 to FIG. 22 will be described as necessary.

First, referring to FIG. 23, an overview of the semiconductor module 10D will be described.

The semiconductor module 10D includes the semiconductor cube 100B, the TCI router chip 300D, and the adhesive layer 400. The semiconductor module 10D may include the bump layer 500, the package substrate 600, and the bump layer 700. The semiconductor module 10D includes a configuration in which the semiconductor cube 100A and the TCI router chip 300B of the semiconductor module 10B are replaced with the semiconductor cube 100B and the TCI router chip 300D. A configuration other than the semiconductor cube 100B and the TCI router chip 300D of the semiconductor module 10D is similar to the semiconductor module 10B. The same configuration as the semiconductor module 10B will be described as required in the description of the semiconductor module 10D.

The semiconductor cube 100B includes a sub-semiconductor cube 101A and the plurality of DRAM chips 110D. The semiconductor cube 100B includes a first surface 142D parallel to the direction D2 and the direction D3, and a second surface 144D parallel to the first surface 142D while opposing the first surface 142D with respect to the direction D1. The semiconducting cube 100 also includes a second side surface 146D parallel to the directions D1 and D2 and perpendicular to the first surface 142 and second surface 144, and a fourth side surface 148D parallel to the second side surface 146D, and perpendicular to and adjacent to the first surface 142 and second surface 144. The second side surface 146D abuts against the adhesive layer 400 and is positioned to face the second side surface 304 of the TCI router chip 300D, and the semiconductor cube 100B is arranged on the second side surface 304 of the TCI router chip 300D.

The sub-semiconductor cube 101A includes a configuration in which logic chips 200 and the SRAM chip 110C are stacked in the direction D1. The logic chip 200 is electrically connected to the SRAM chip 110C.

The configuration and the function of the logic chip 200 are the same as the configurations and the functions described in the section “1-1-1. Overview of Semiconductor Module 10,” the section “1-1-2. Overview of Inductor 272 and Inductor 372,” the section “1-1-3. Circuit Configuration of Semiconductor Module 10,” and the section “1-2. Overview of Semiconductor Cube 100,” and will be described as necessary.

The SRAM chip 110C differs from the SRAM chip 110 in that it relates to an inductor layer 170C (see FIG. 25). The rest of the SRAM chip 110C is similar to the SRAM chip 110. Here, the same functions and configurations as the SRAM chip 110 will be described as required. The SRAM chip 110C includes a first surface 102C which is an exposed surface of the SRAM chip 110C, a second surface 104C which is an exposed surface of the SRAM chip 110C and opposite to the first surface 102C, the plurality of inductors 172 (fourth inductor), and a plurality of inductors 172C (fifth inductor). The first side surface 102C faces and contacts the first side 202 of the logic chip 200. Similar to the sub-semiconductor cube 101, the plurality of through electrodes 160 is exposed to the first surface 102C, and is bonded to the through electrode 260 exposed to the first surface 202 of the logic chip 200 using fusion bonding. The first surface 102C and the second surface 104C are parallel to the first surface 142D and the second surface 144D.

Each of the plurality of DRAM chips 110D has the same configuration including a first surface 102D which is an exposed surface of the DRAM chip 110D, a second surface 104D which is an exposed surface of the DRAM chip 110D and opposite to the first surface 102D, a plurality of inductors 172AD (sixth inductor), and a plurality of inductors 172AU (seventh inductor). The plurality of DRAM chips 110D are stacked in the direction D1. The plurality of DRAM chips 110D includes three DRAM chips 110D as an example. The second surface 104D of the first DRAM chip 110D and the second surface 104D of the second DRAM chip 110D are bonded to each other using fusion bonding, and the second surface 102D of the third DRAM chip 110D is bonded to the first surface 102D of the second DRAM chip 110D using fusion bonding. The first surface 102D of the first DRAM chip 110D is bonded to the second surface 104C of the SRAM chip 110C using fusion bonding.

In addition, the sub-semiconductor cube 101A, and the number, the order of the stacking, the surface to be bonded, or the like of the plurality of DRAM chips 110D is an example and is not limited to the example shown here. The sub-semiconductor cube 101A, and the number, the order of the stacking, the surface to be bonded, or the like of the plurality of DRAM chip 110D can be appropriately changed depending on the specifications, the application, or the like of the semiconductor module 10D.

Next, referring now to FIG. 24, the overview of the TCI router chip 300D and the semiconductor cube 100B in the semiconductor module 10D will be described.

The TCI router chip 300D is connected with the plurality of semiconductor cubes 100B using inductor communication. More specifically, the TCI router chip 300D is connected to the plurality of semiconductor cubes 100B via the inductor 372, the inductor 172, and the inductor 272.

The SRAM chip 110C includes the plurality of TCI-IOs 112, a plurality of TCI-IOs 112A, the DRAMIO 311, and the plurality of logic modules 111. The plurality of logic modules 111, the plurality of TCI-IOs 112 and the plurality of TCI-IOs 112A included in the SRAM chip 110C are electrically connected to the DRAMIO 311. Although the SRAM chip 110C includes the plurality of TCI-IOs 112, the plurality of TCI-IOs 112A, and the plurality of logic modules 111, in FIG. 24, the number of the TCI-IOs 112, the number of the TCI-IOs 112A, and the number of the logic modules 111 in the SRAM chip 110C are reduced to one respectively for clarity of the drawings.

The logic module 111 includes configurations and functions similar to those of the logic module 111 described in the section “1-1-3. Circuit Configuration of Semiconductor Module 10” and the section “1-2. Overview of Semiconductor Cube 100”, and will be described as necessary. The TCI-IO 112 includes the same configuration and functions as those of the TCI-IO 112 described in the section “Second Embodiment” and will be described as required. The configuration and functions of the DRAMIO 311 are the same as the configurations and functions described in the section “1-1-3. Circuit Configuration of Semiconductor Module 10”, the section “1-3. Overview of TCI Router Chip 300”, and the section “Second Embodiment”, and will be described as required.

The TCI-IO 112A includes a configuration in which the inductor 172 of the TCI-IO 112 is replaced with the inductor 172C. Other configurations of the TCI-IO 112A are similar to the TCI-IO 112 and will be described as required.

The inductor 272 (see FIG. 23) and inductor 172 included in the logic chip 200 have the ability to inductively communicate with the inductor 372 of the TCI router chip 300 in a non-contact manner. The inductor 172C differs from the inductor 172 in that it communicates inductively with the inductor 172AD contained in the DRAM chip 110D. Other points of the inductor 172C are similar to the inductor 172. Here, the same functions and configurations as the inductor 172 will be described as necessary.

The DRAM chip 110D includes a plurality of TCI-IOs 112B, a plurality of TCI-IOs 112C, and a plurality of DRAM modules 111C. The plurality of TCI-IOs 112B (parallel-series conversion circuit 113) and the plurality of TCI-IOs 112C (parallel-series conversion circuit 113) are electrically connected to the plurality of DRAM modules 111C. Although the DRAM chip 110D includes the plurality of TCI-IOs 112B, the plurality of TCI-IOs 112C, and the plurality of DRAM modules 111C, the number of the TCI-IO 112B, the TCI-IO 112C, and the DRAM module 111C in the DRAM chip 110C is reduced to one in FIG. 24 for the sake of clarity of the drawings, similar to the SRAM chip 110C.

The TCI-IO 112B includes a configuration in which the inductor 172 of the TCI-IO 112 is replaced with the inductor 172AD, and the TCI-IO 112C includes a configuration in which the inductor 172 of the TCI-IO 112 is replaced with the inductor 172AU. Other configurations of the TCI-IO 112B and the TCI-IO 112C are similar to the TCI-IO 112 and will be described as required. The configuration and functions of the DRAM module 111C are the same as those of the DRAM module 111A described in the section “Second Embodiment”, and are described as required.

The inductor 172AD included in the DRAM chip 110D is different from the inductor 172 in that it communicates with the inductor 172C included in the adjacent SRAM chip 110C or the inductor 172AU included in the adjacent DRAM chip 110D. The inductor 172AU included in the DRAM chip 110D is different from the inductor 172 in that it communicates inductively with the inductor 172AD included in the adjacent DRAM chip 110D. Other points of the inductor 172AD and the inductor 172AU are similar to the inductor 172. Here, the same functions and configurations as the inductor 172 will be described as necessary.

The TCI router chip 300D includes a configuration in which the DRAMIO 311 in the TCI router chip 300 is replaced by a DRAM controller 319A. The configuration of the TCI router chip 300D other than the DRAM controller 319A is the same as that of the TCI router chip 300. In addition, as noted above, the SRAM chip 110C includes the DRAMIO 311.

The DRAM controller 319A is electrically connected to the R 318g. The DRAM controller 319A is, for example, an IP core. Although not shown, the DRAM controller 319A includes the NI 317 as well as the memory controller 319. In addition, the DRAM controller 319A may not include the NI 317, the NI 317 may be located outside the DRAM controller 319A, and the DRAM controller 319A may be electrically connected to the R 318 via the NI 317.

The DRAM controller 319A is connected to the DRAMIO 311 and the memory module 111 using inductor communication, for example, via the R 318g, the R 318b, the TCI-IO 312b (inductor 372) and TCI-IO 112 (inductor 172). Further, the DRAMIO 311 and memory module 111 are also connected to the DRAM module 111C via the TCI-IO 112A (inductor 172C), the TCI-IO 112B (inductor 172AD), the TCI-IO 112C (inductor 172AU), using inductor communication. Further, the DRAM controllers 319A are also electrically connected to the logic module 211 included in the logic chip 200, for example, via the R 318g, the R 318a, the TCI-IO 312a (inductor 372), and the TCI-IO 212 (inductor 272) included in the logic chip 200. That is, the DRAM controller 319A has a function of transmitting and receiving signals to and from the logic module 211 and the DRAM module 111A using inductor communication.

The semiconductor module 10D is configured such that both the logic chip 200 and the SRAM chip 110C are in inductive communication with the TCI router chip 300D. Further, the semiconductor module 10D includes a configuration in which the SRAM chip 110C and the DRAM chip 110D can carry out inductor communication, as well as a configuration in which the neighboring chips of the plurality of DRAM chips 110D can carry out inductor communication. The semiconductor module 10D can achieve the same advantages as the semiconductor module 10B.

Next, referring to FIG. 25 and FIG. 26, a schematic of a cross-sectional construction of the SRAM chip 110C and the DRAM chip 110D will be described.

As shown in FIG. 25, the SRAM chip 110C includes a transistor layer 130C, a wiring layer 150C, and the inductor layer 170C. The first surface 102C of the SRAM chip 110C is parallel to the directions D2 and D3, and is an exposed surface of the transistor layer 130C. The second surface 104C of the SRAM chip 110C is parallel to the directions D2 and D3, and is an exposed surface of the inductor layer 170C.

The transistor layer 130C and the wiring layer 150C include the same structure as the transistor layer 130 and the wiring layer 150. The inductor layer 170C includes the insulating layer 182, the inductor 172, and the inductor 172C. Each of the inductor 172 and the Inductor 172C is electrically connected to the through electrode 160, for example, via the wiring 180, the wiring 178, the wiring 166, and the wiring 163. The SRAM chip 110C can transmit and receive signals (data) via the inductor 172 and inductor 172C.

As shown in FIG. 26, the DRAM chip 110D includes a transistor layer 130D, a wiring layer 150D, and an inductor layer 170D. The first surface 102D of the DRAM chip 110D is parallel to the directions D2 and D3, and is an exposed surface of the transistor layer 130D. The second surface 104D of the SRAM chip 110C is parallel to the directions D2 and D3, and is an exposed surface of the inductor layer 170D. The first surface 102D and the second surface 104D are parallel to the first surface 142D and the second surface 144D.

A portion of the wiring 163 in the transistor layer 130D, as compared to the transistor layer 130A, functions as the inductor 172AD. Other configurations of the transistor layer 130D are similar to the transistor layer 130A. The wiring layer 150D includes a configuration similar to that of the wiring layer 150A. The inductor layer 170D differs from the inductor layer 170A in that the inductor 172A of the inductor layer 170A replaces the inductor 172AU. Other configurations of the inductor layer 170D are similar to the inductor layer 170A. Therefore, the layers and wirings constituting the transistor layer 130D, the wiring layer 150D and the inductor layer 170D will not be described.

Various configurations of the semiconductor modules 10, 10A, 10B, 10C, and 10D exemplified as an embodiment of the present invention can be appropriately replaced, as long as they do not conflict with each other without departing from the spirit of the present invention. Further, various configurations of the semiconductor modules 10, 10A, 10B, 10C, and 10D exemplified as an embodiment of the present invention can be appropriately combined as long as they do not conflict with each other without departing from the spirit of the present invention. Further, technical matters common to the respective embodiments are included in the respective embodiments without explicit description. Further, any semiconductor module that a person skilled in the art may add, delete, or modify the design of components, or add, omit, or modify processes based on the semiconductor module disclosed in this specification and drawings, is included within the scope of the present invention as long as it includes the gist of the present invention.

It is to be understood that the present invention provides other effects that are different from the effects provided by the aspects of the embodiments disclosed herein, and those that are obvious from the description herein or that can be easily predicted by a person skilled in the art.

What is claimed is:

1. A semiconductor module comprising:
a first semiconductor chip including a first surface parallel to a first direction and a second direction intersecting the first direction, and a second surface parallel to the first surface; and
a semiconductor cube arranged on the second surface, including a sub-semiconductor cube in which a second semiconductor chip and a logic chip electrically connected to the second semiconductor chip are stacked in the first direction, wherein
the logic chip includes a plurality of first inductors arranged parallel to a third direction perpendicular to the first and second directions,
the first semiconductor chip includes a plurality of routers and a plurality of second inductors arranged parallel to the second surface,
a plurality of circuits within the first semiconductor chip is electrically connected using the plurality of routers, and
the logic chip and the first semiconductor chip are configured to enable contactless communication using the plurality of first inductors and the plurality of second inductors.

2. The semiconductor module of claim 1, wherein
the logic chip controls the plurality of routers via the plurality of first inductors and the plurality of second inductors, and is configured to connect the plurality of circuits in the first semiconductor chip and the second semiconductor chip.

3. The semiconductor module of claim 1, wherein
each of the plurality of routers includes a switch.

4. The semiconductor module of claim 1, wherein
the logic chip includes a first electrode, and
the second semiconductor chip includes a second electrode configured so as to join with the first electrode by fusion bonding.

5. The semiconductor module of claim 1, wherein
the semiconductor cube includes a plurality of the sub-semiconductor cubes stacked in the first direction, and
the plurality of sub-semiconductor cubes is configured to be capable of contactless communication with each other via the plurality of second inductors using the plurality of first inductors included in each of the sub-semiconductor cubes.

6. The semiconductor module of claim 1, wherein
the semiconductor cube includes:
at least one type of memory chip different from the second semiconductor chip; and
a configuration in which the sub-semiconductor cube and the at least one type of memory chip are stacked in the first direction,
the at least one type of memory chip includes a plurality of third inductors, and
at least one second inductor of the plurality of second inductors is capable of contactless communication with at least one third inductor of the plurality of third inductors.

7. The semiconductor module of claim 5, wherein
the semiconductor module includes a plurality of the semiconductor cubes, and
the plurality of the semiconductor cubes is arranged spaced apart from one another on the second surface.

8. The semiconductor module of claim 5, wherein
the plurality of sub-semiconductor cubes is arranged spaced apart from one another on the second surface.

9. The semiconductor module of claim 1, wherein
the semiconductor cube includes:
at least one type of memory chip different from the second semiconductor chip; and
a configuration in which the sub-semiconductor cube and the at least one type of memory chip are stacked in the first direction,
the second semiconductor chip is arranged parallel to the third direction and includes a plurality of fourth inductors capable of contactless communication with each of the plurality of second inductors and a plurality of fifth inductors different from the plurality of fourth inductors, and
the at least one type of memory chip includes a plurality of sixth inductors capable of contactless communication with each of the plurality of fifth inductors.
